(19) United States
(12) Patent Application Publication
(10) Pub. No.: US 2026/0032895 A1
(43) Pub. Date: Jan. 29, 2026

(54) Memory Circuitry And Methods Used In Forming Memory Circuitry

(71) Applicant: Micron Technology, Inc., Boise, ID (US)

(72) Inventors: Brenda Li, Boise, ID (US); Cheng Li, Boise, ID (US)

(73) Assignee: Micron Technology, Inc., Boise, ID (US)

(21) Appl. No.: 19/231,957

(22) Filed: Jun. 9, 2025

Related U.S. Application Data
(60) Provisional application No. 63/675,111, filed on Jul. 24, 2024.

(51) Int. Cl. H10B 12/00; G11C 5/06

(52) U.S. Cl. CPC H10B 12/50; G11C 5/063; H10B 12/09; H10B 12/482; H10B 12/488

(57) ABSTRACT

A method used in forming memory circuitry comprising memory cells comprises forming vertically-alternating insulative tiers and memory-cell tiers. The memory cells individually comprise a horizontal transistor comprising a gate that comprises part of one of a plurality of horizontal conductive access lines that individually directly electrically couple together multiple of the gates of different ones of the horizontal transistors that are in the same memory-cell tier. The access lines extend horizontally from the memory-array region into a connection region. Over a same time period and using the same processing steps, digitlines are formed in the memory-array region that individually directly electrically couple to the horizontal transistors in different ones of the memory-cell tiers and conductive-via constructions are formed in the connection region that individually directly electrically couple to individual of the access lines. Other embodiments, including structure, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory-array region having horizontal tiers in which individual memory cells are received (e.g., arrayed in x and y directions). The stack in the 3D memory-array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-107 are diagrammatic sequential sectional and/or enlarged views of a construction, or portions thereof or alternate and/or additional embodiments, in process in accordance with some embodiments of the invention.

### DETAILED DESCRIPTION OF EXAMPLE EMBODIMENTS

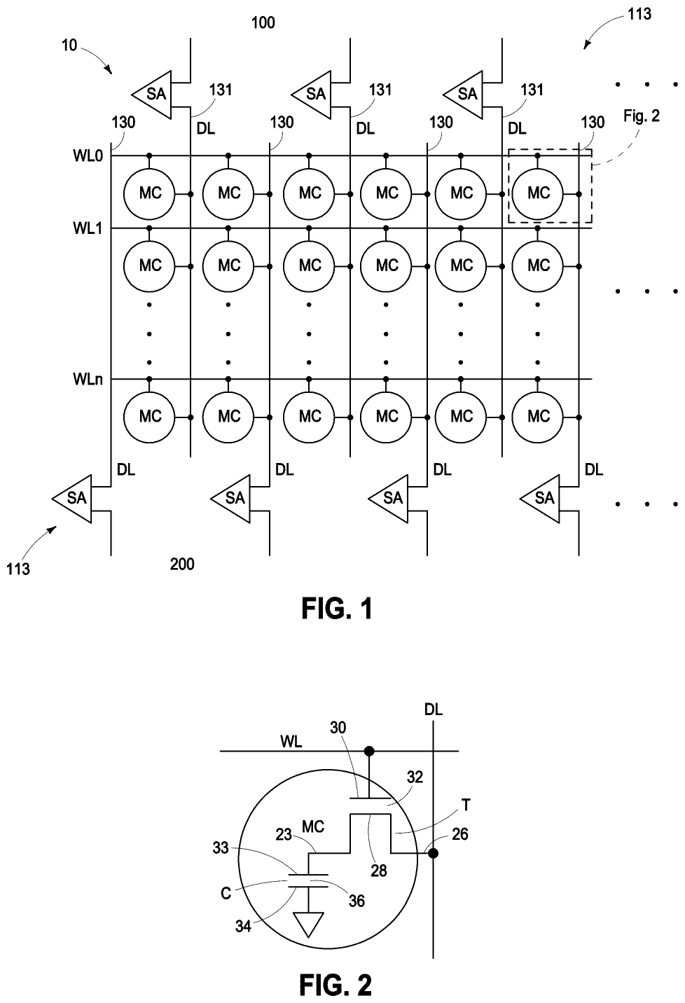

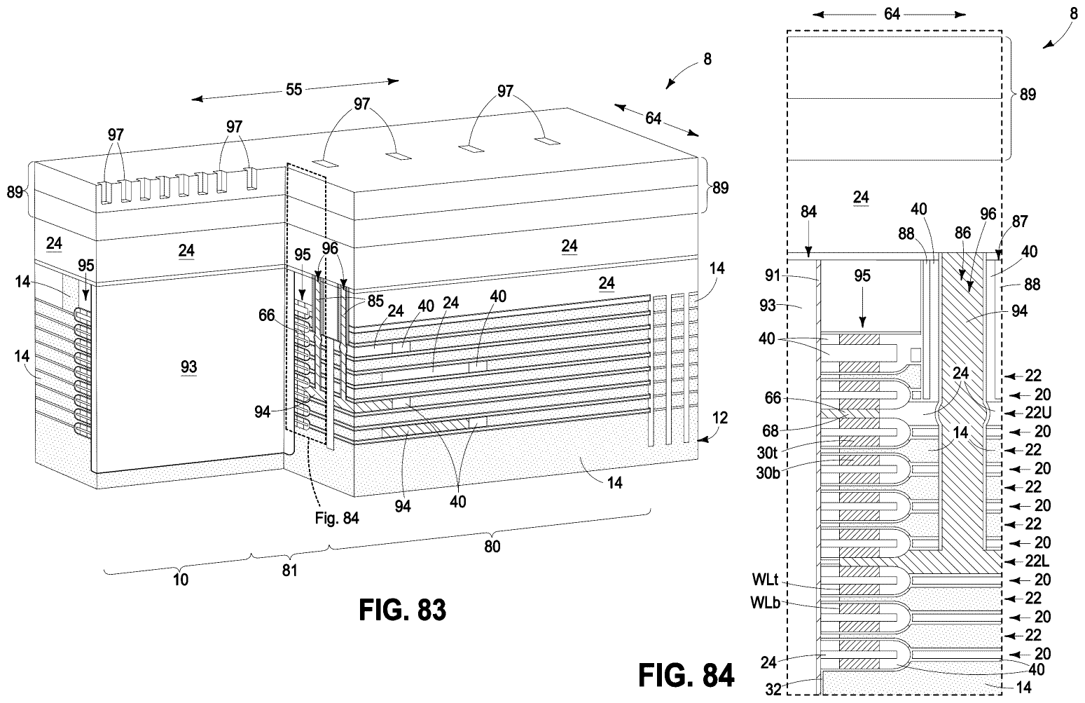

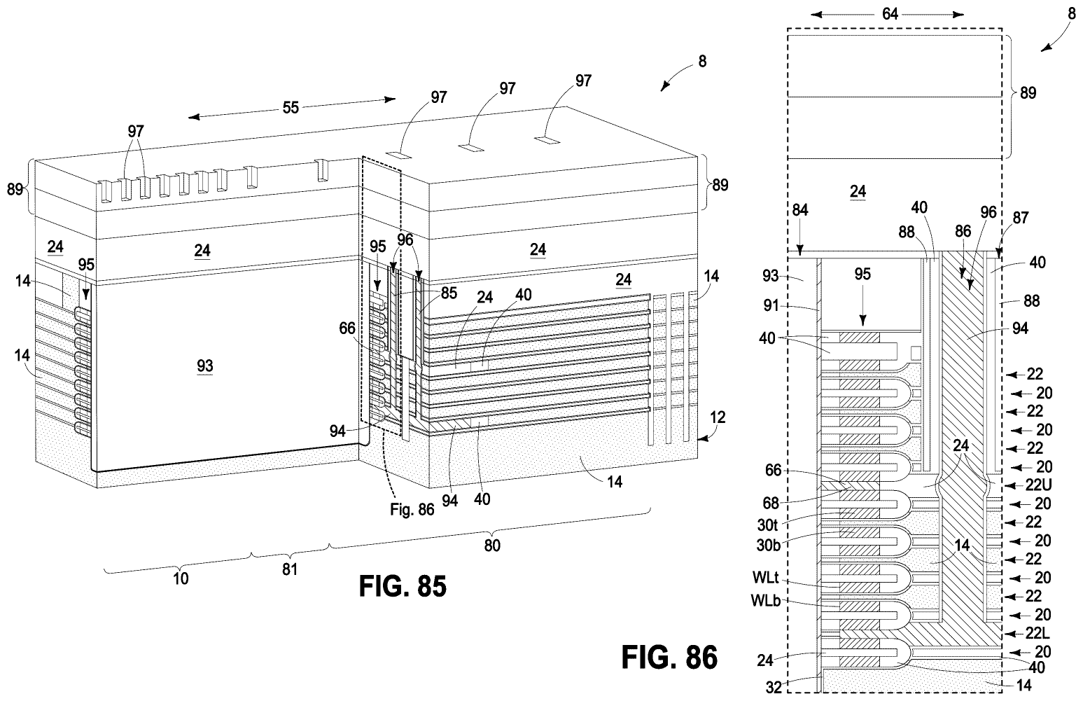

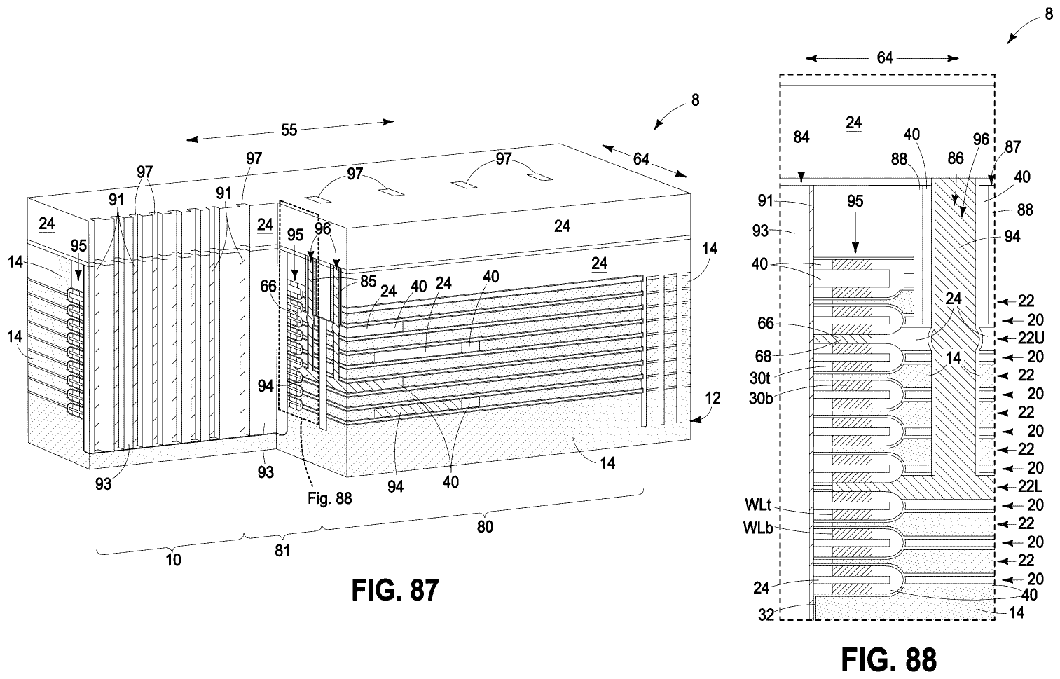

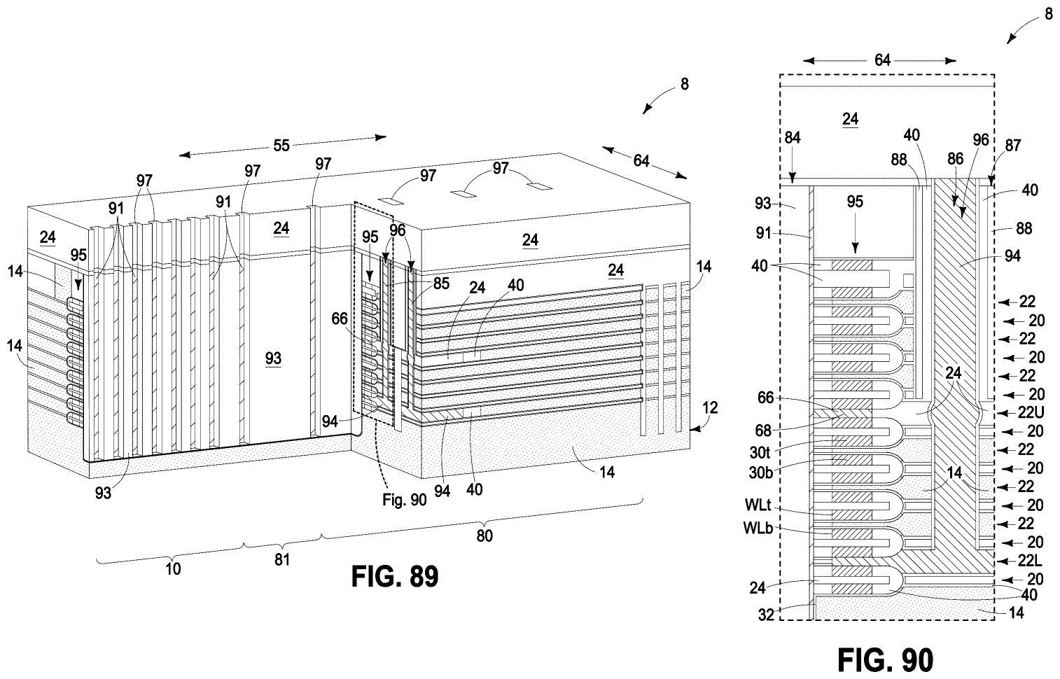

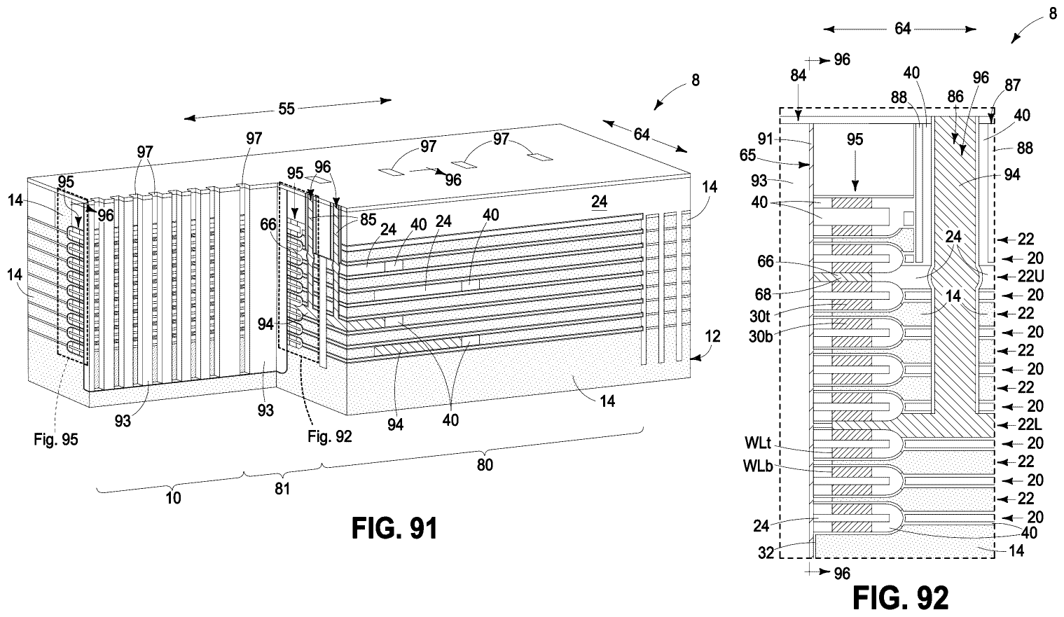

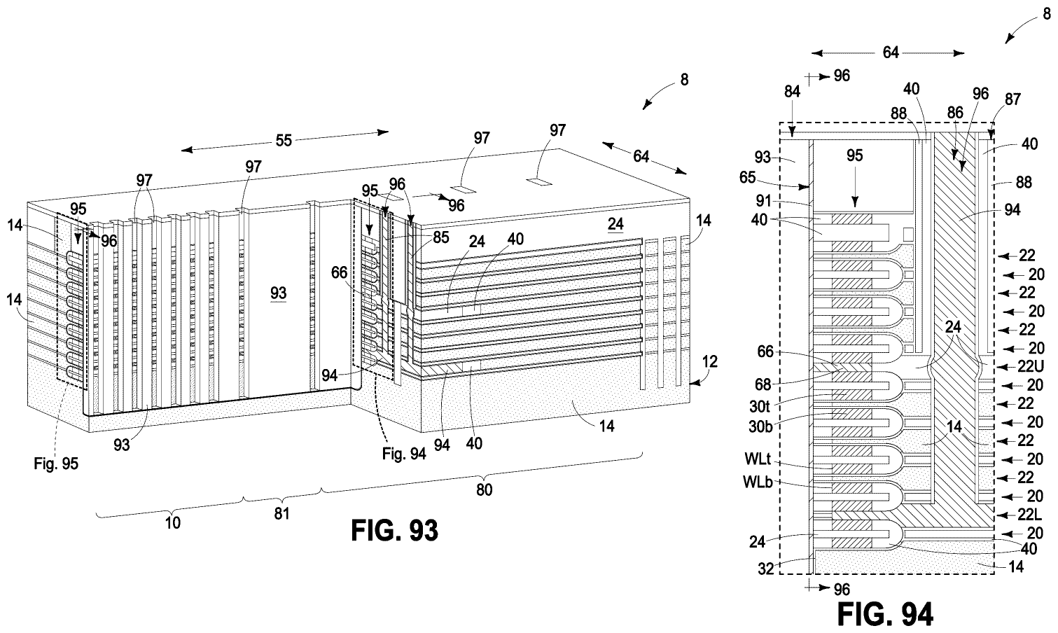

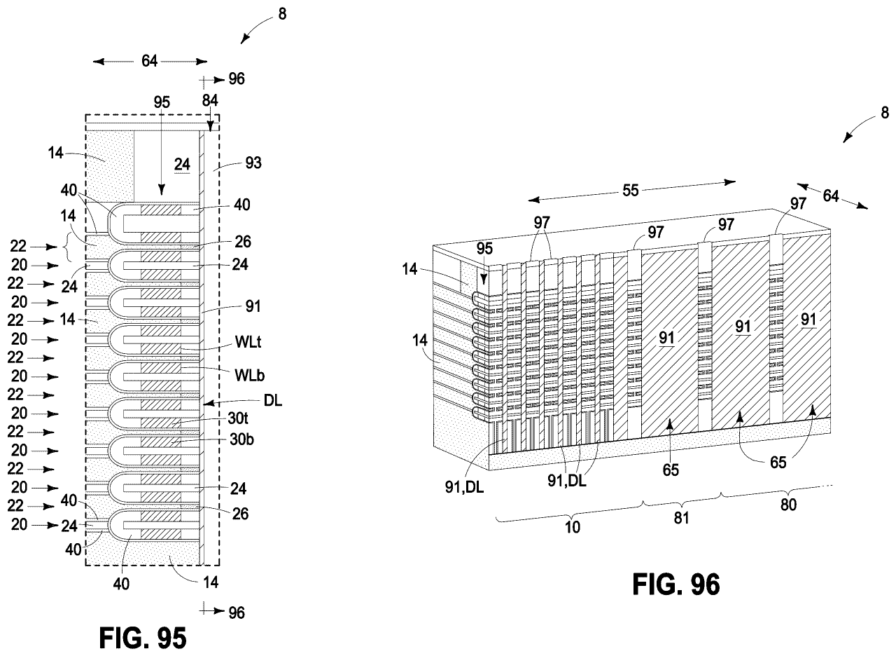

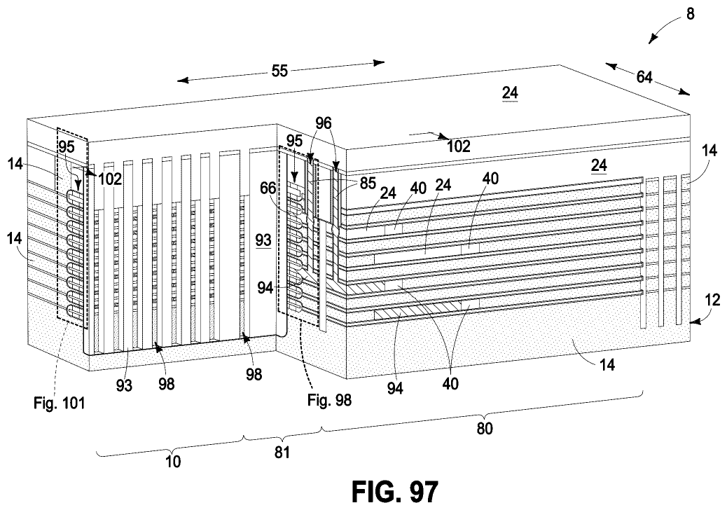

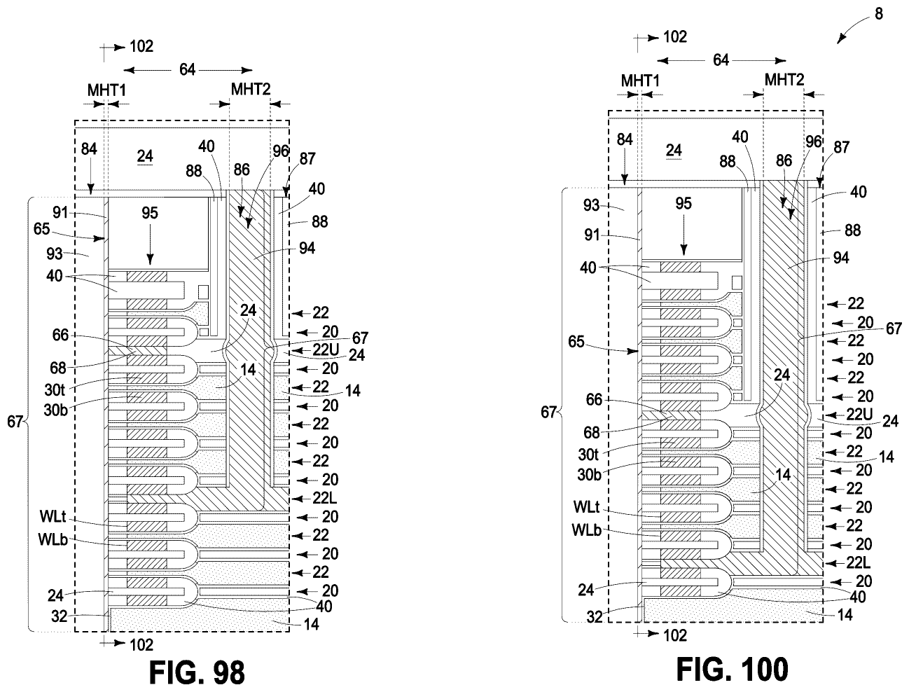

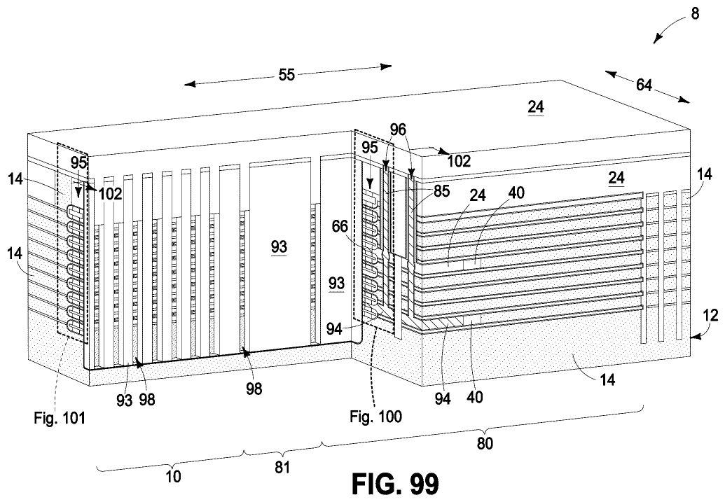

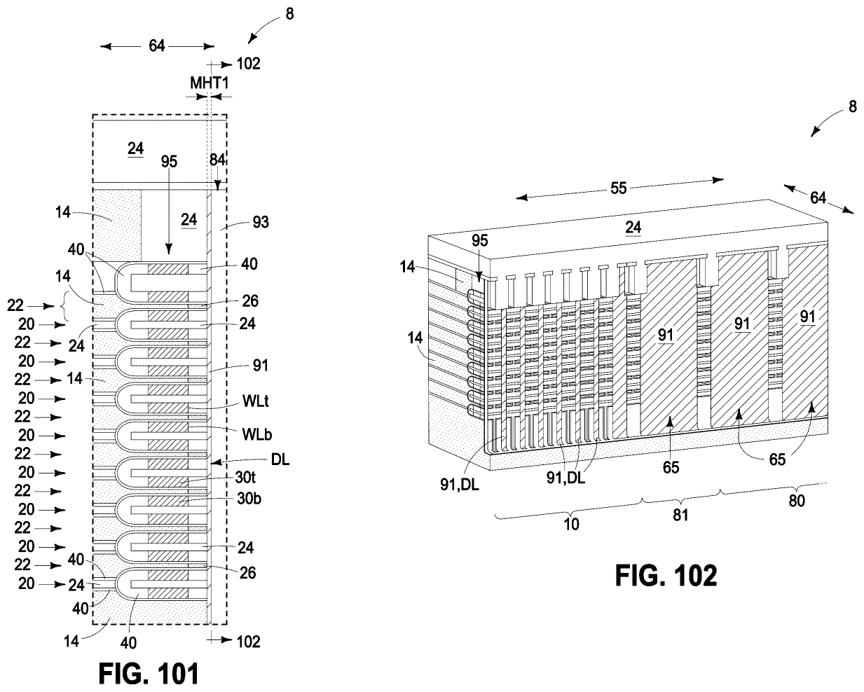

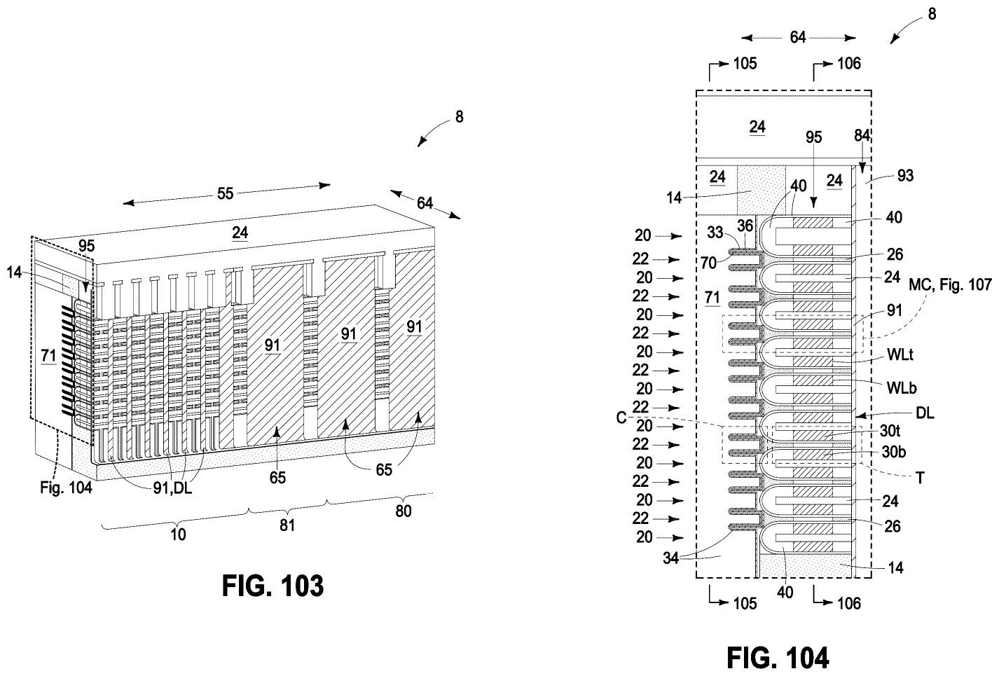

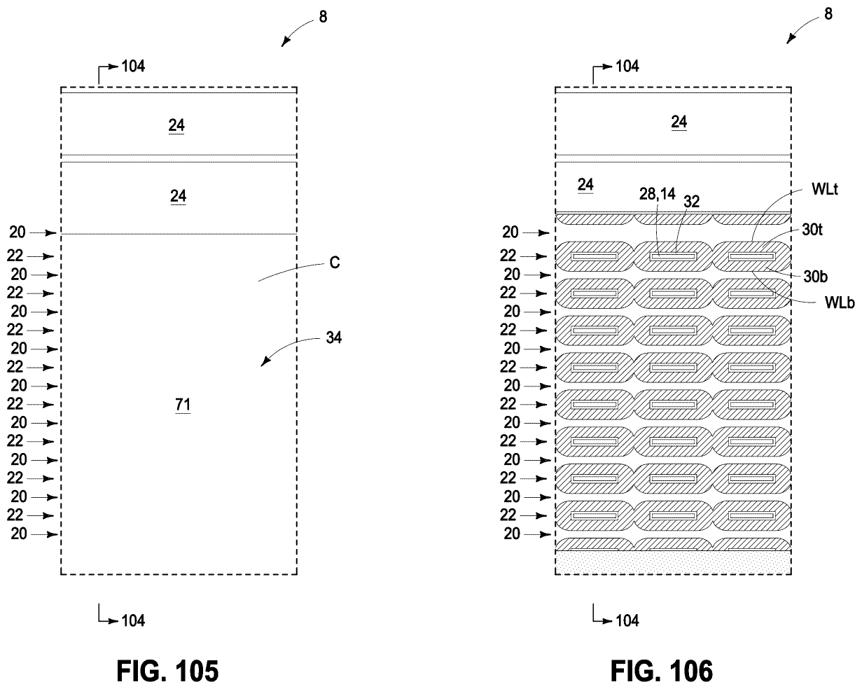

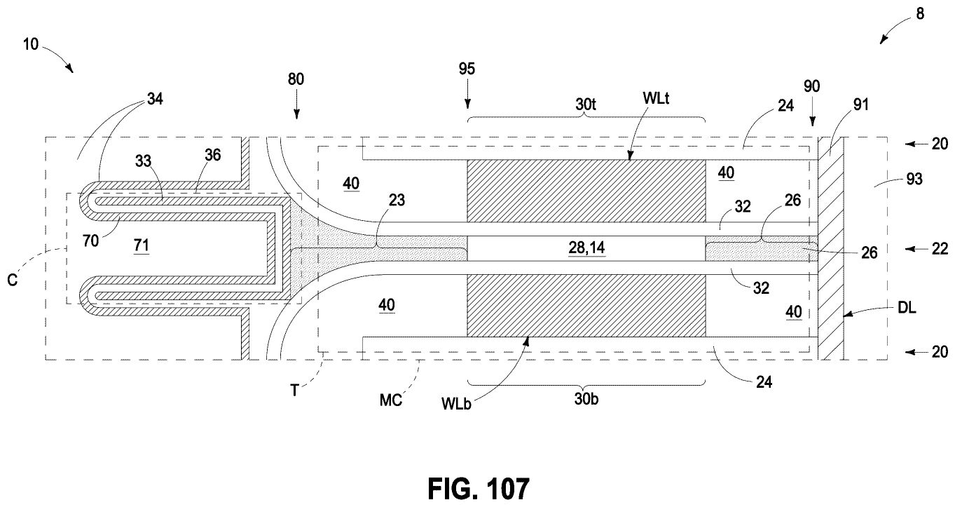

Embodiments of the invention encompass memory circuitry (c.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-107.

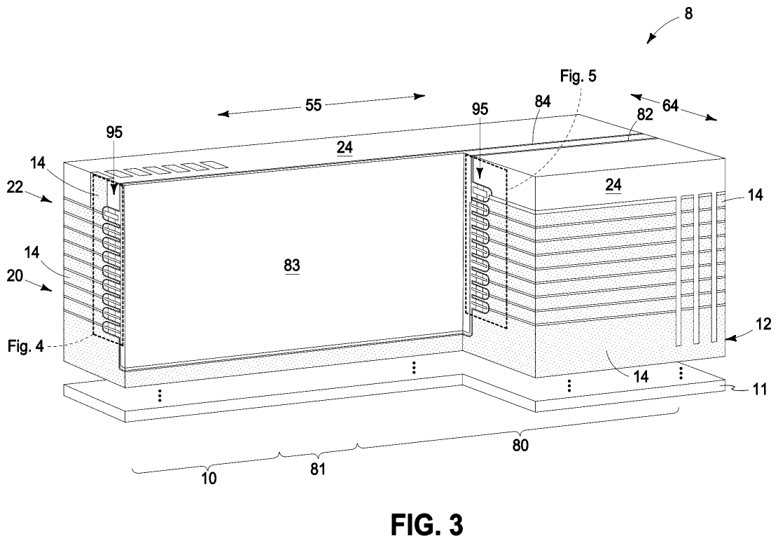

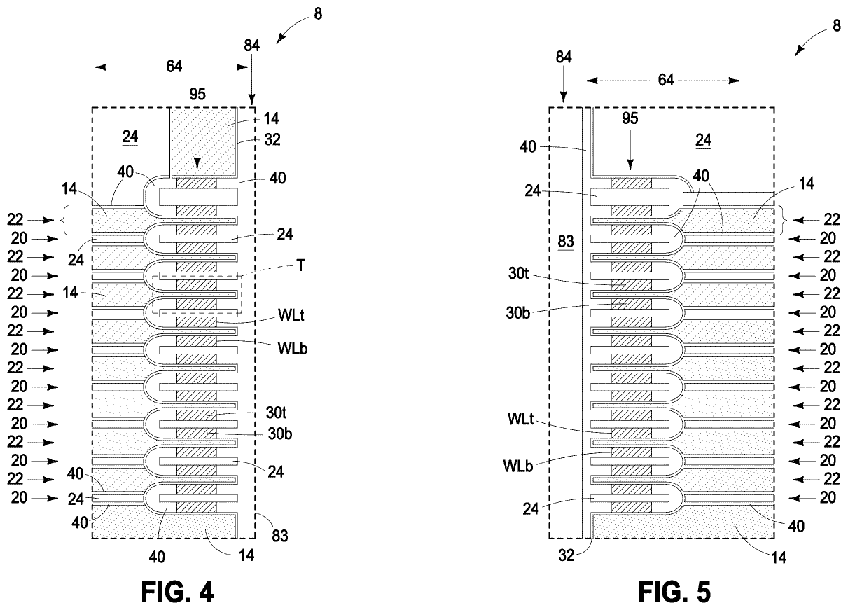

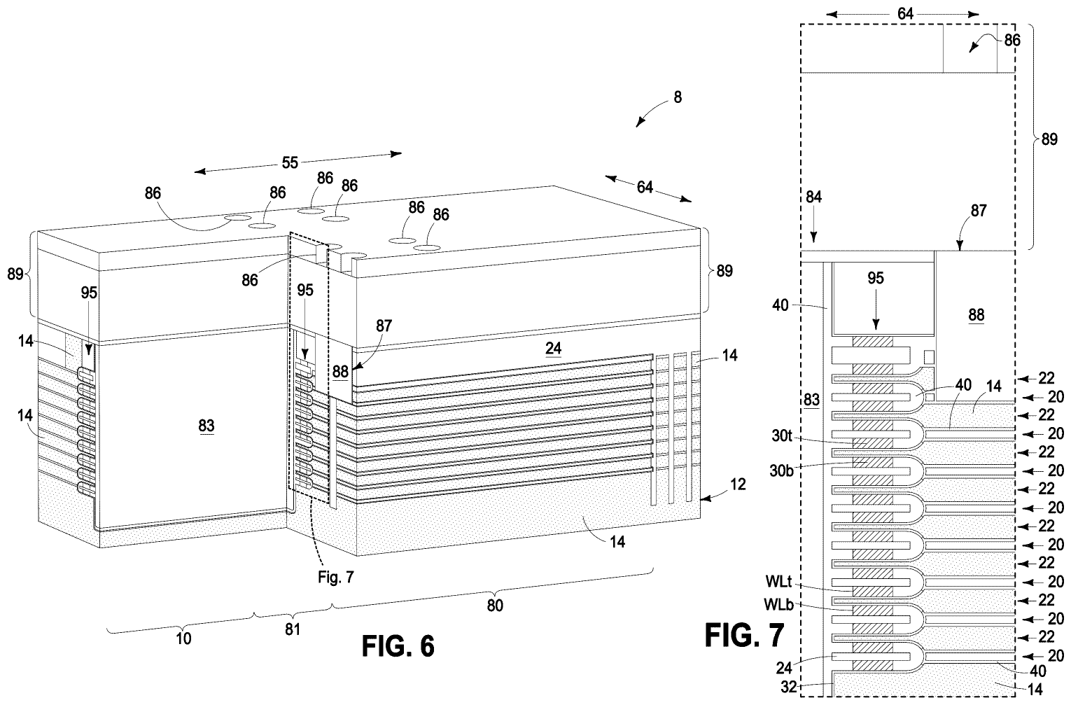

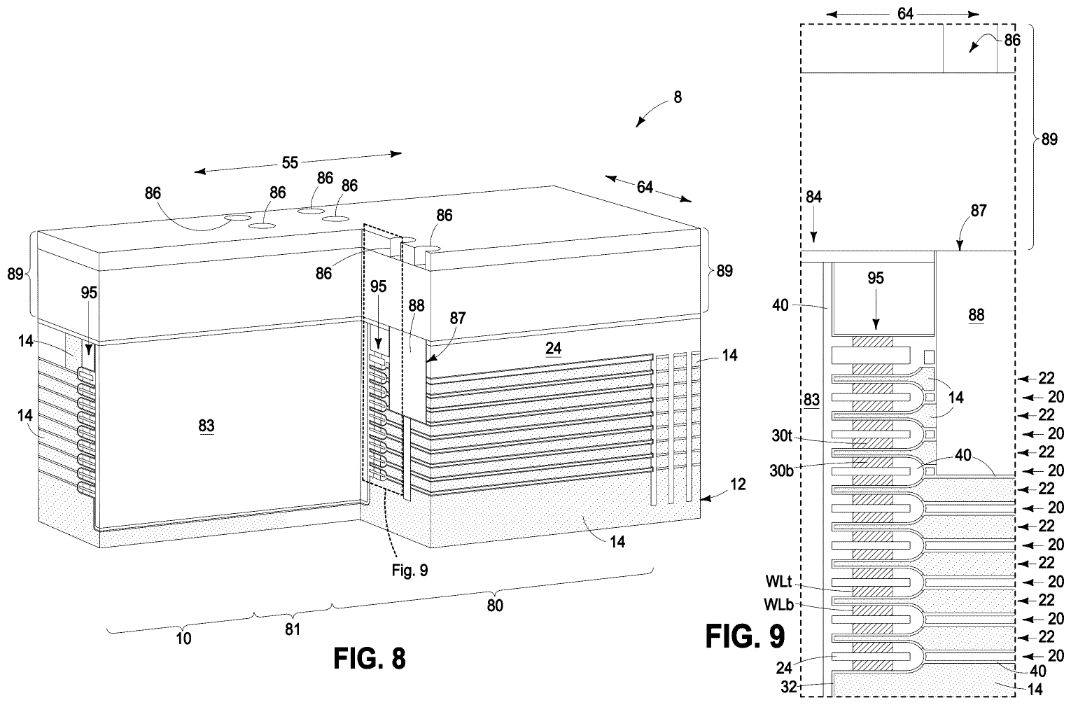

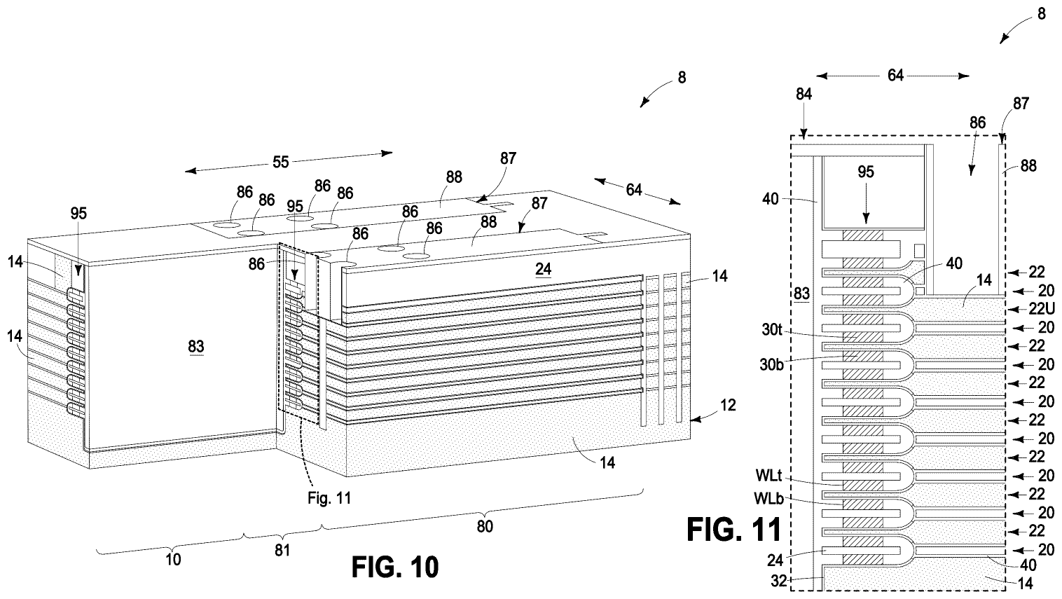

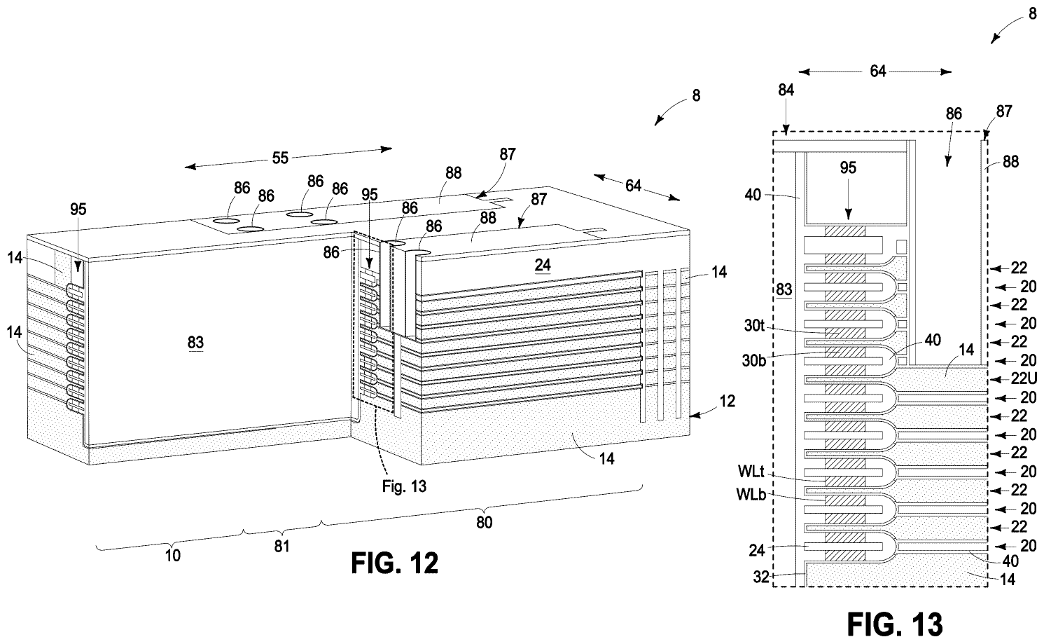

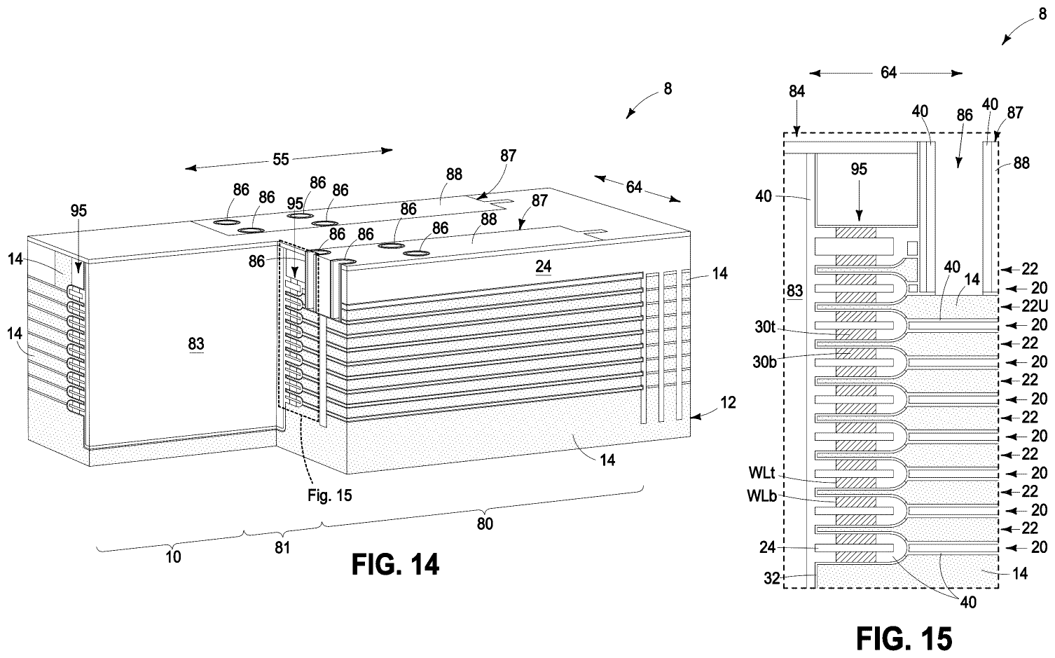

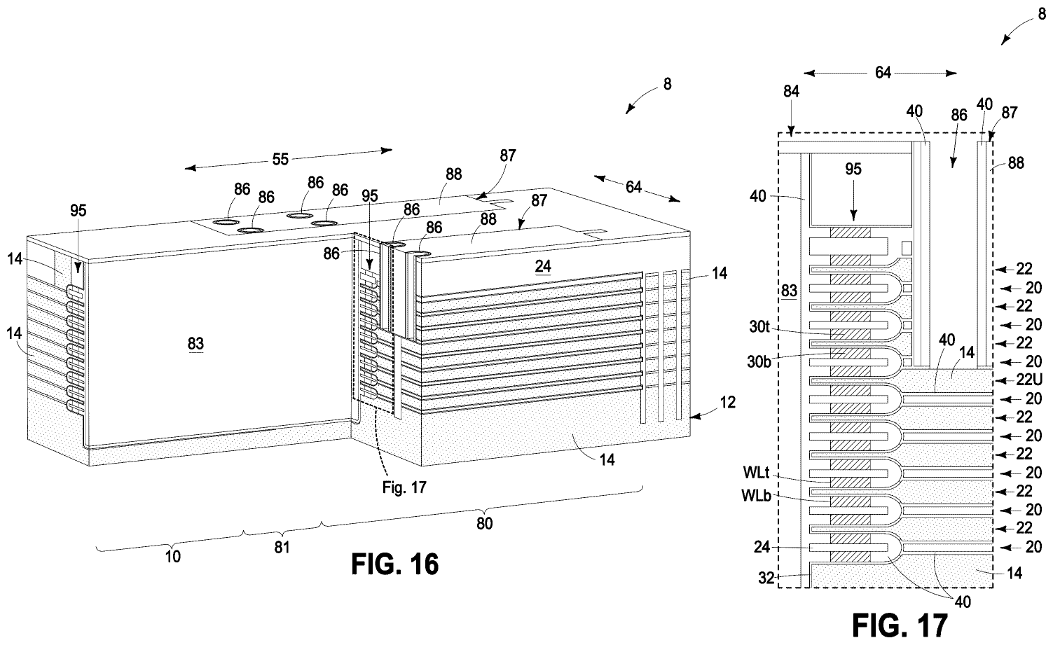

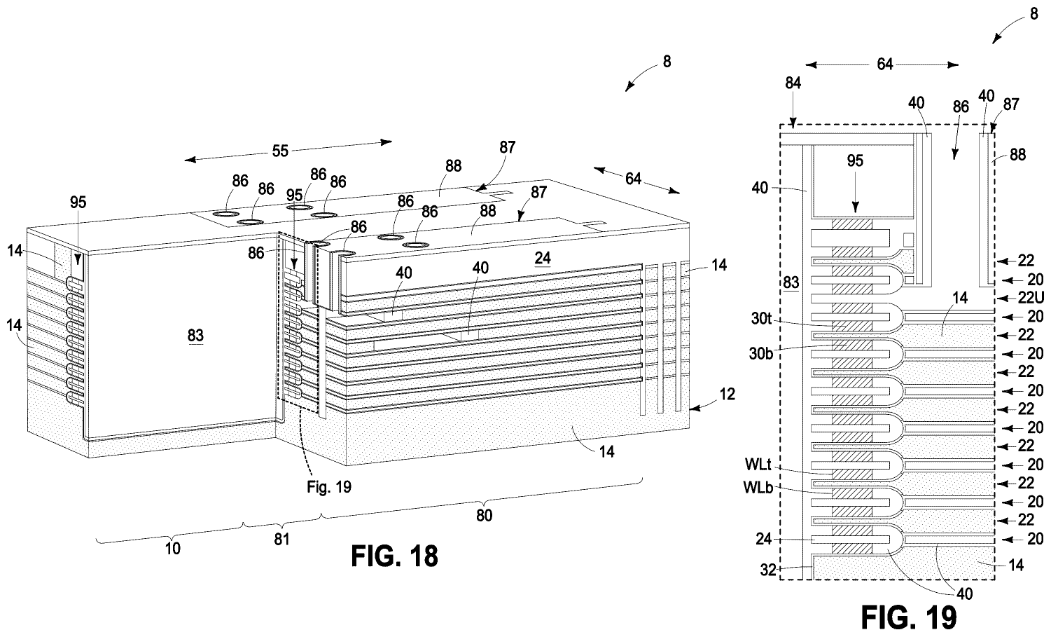

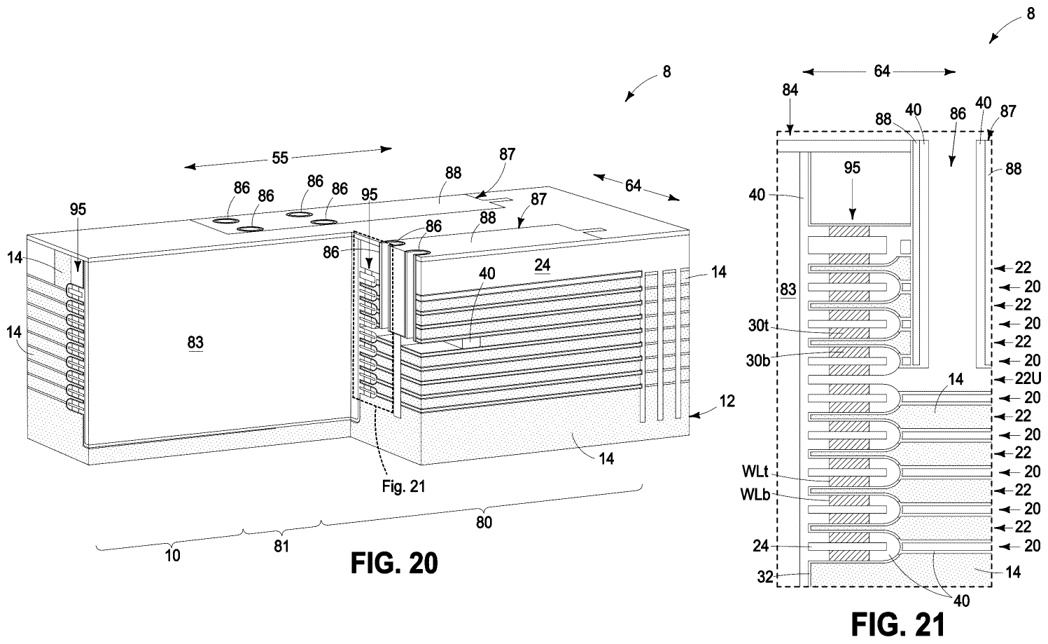

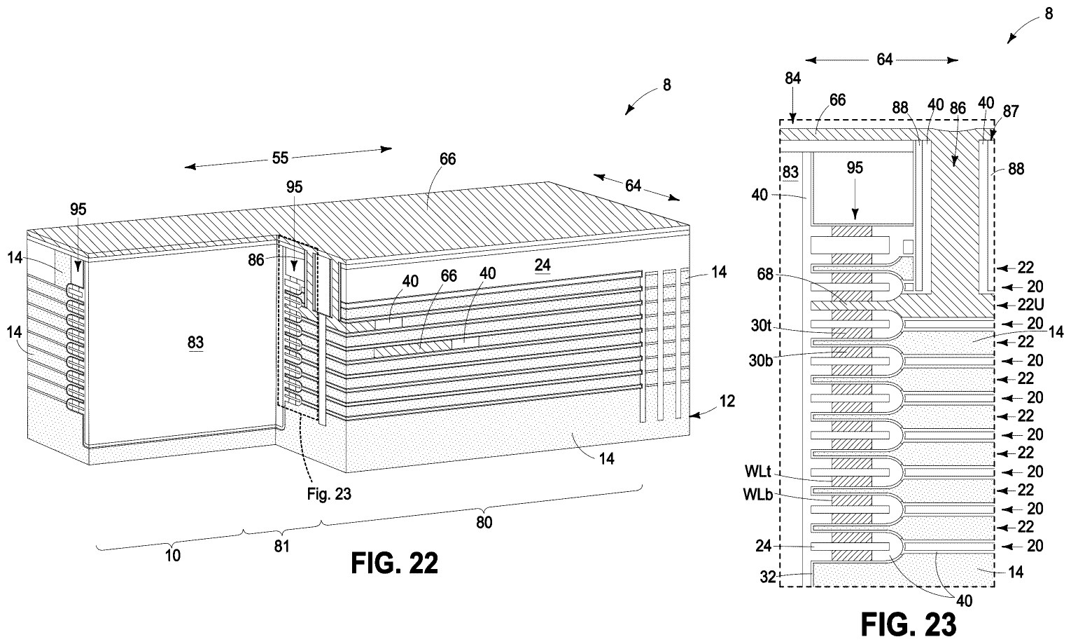

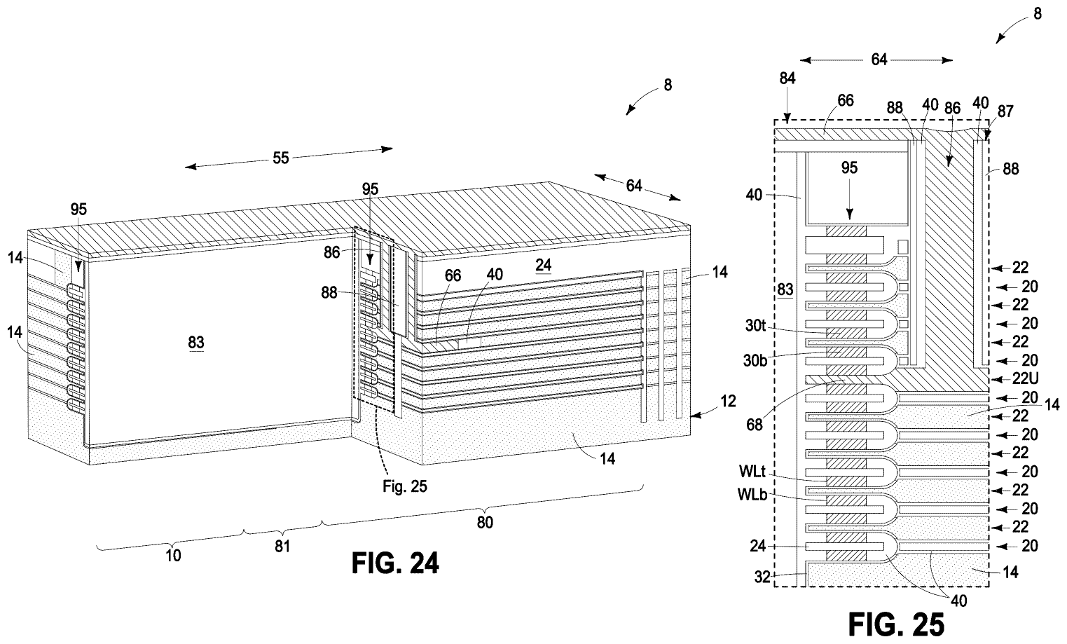

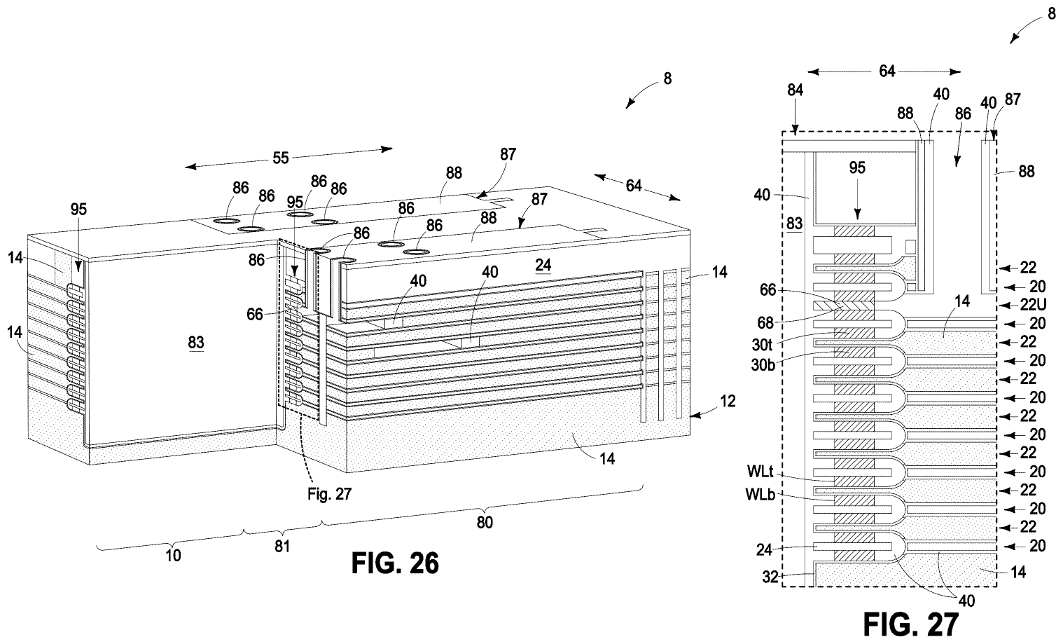

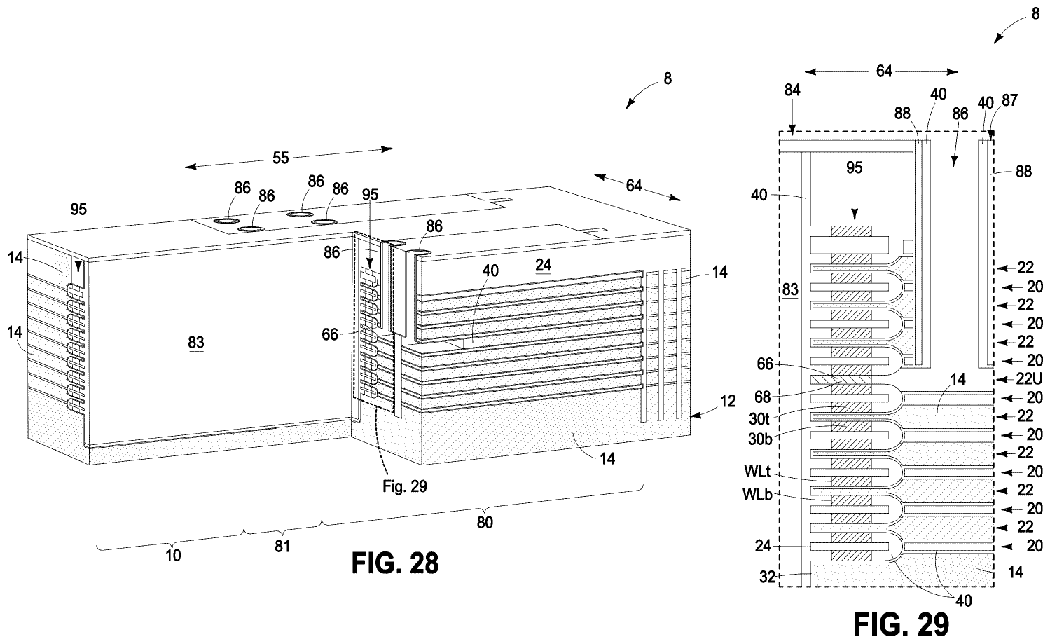

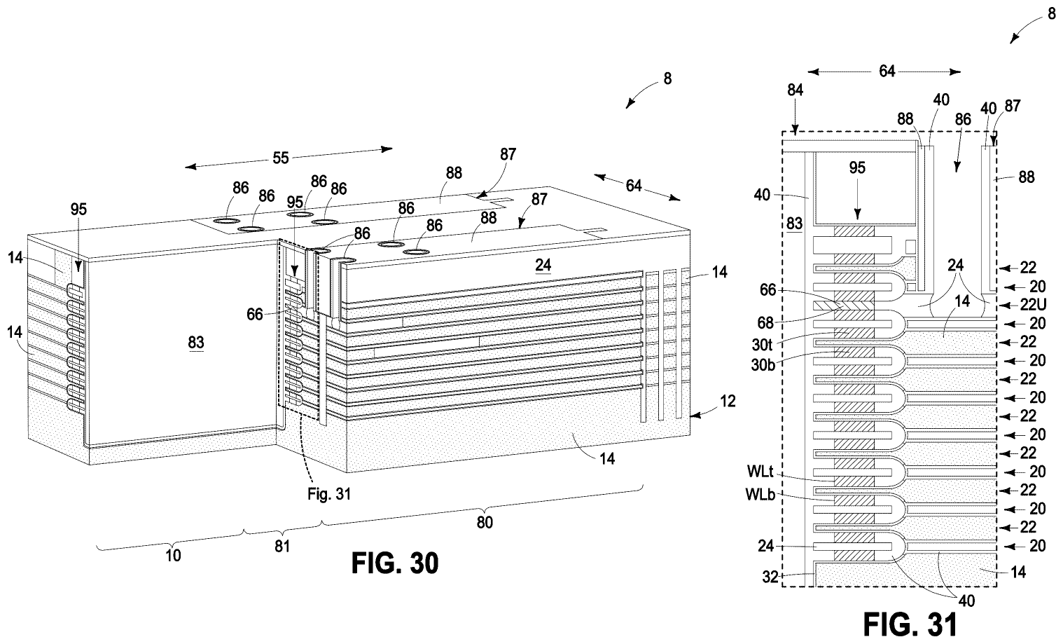

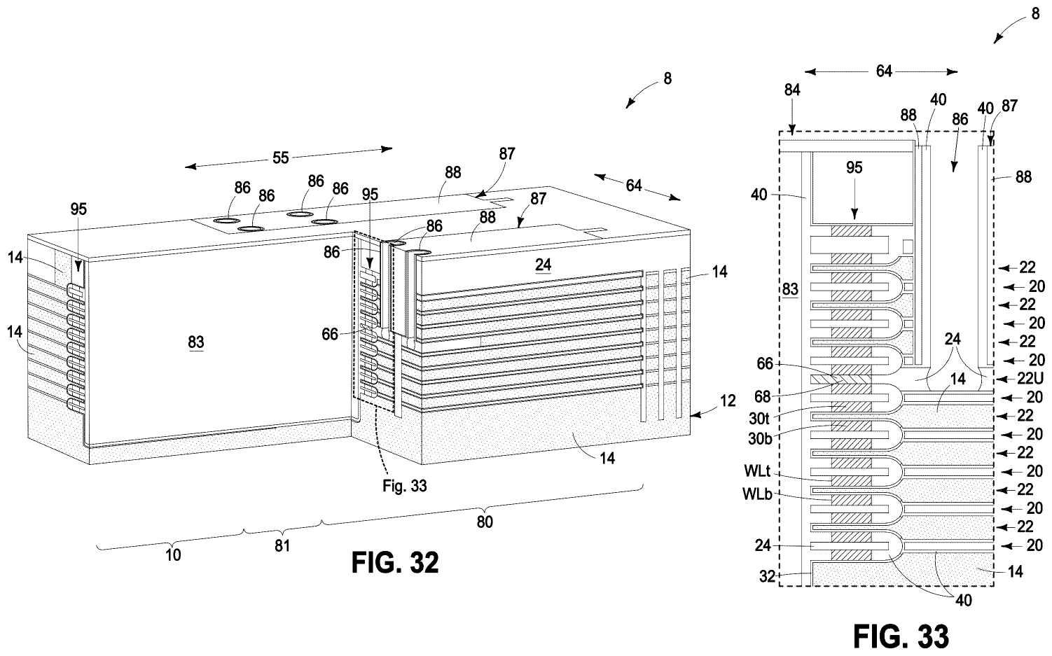

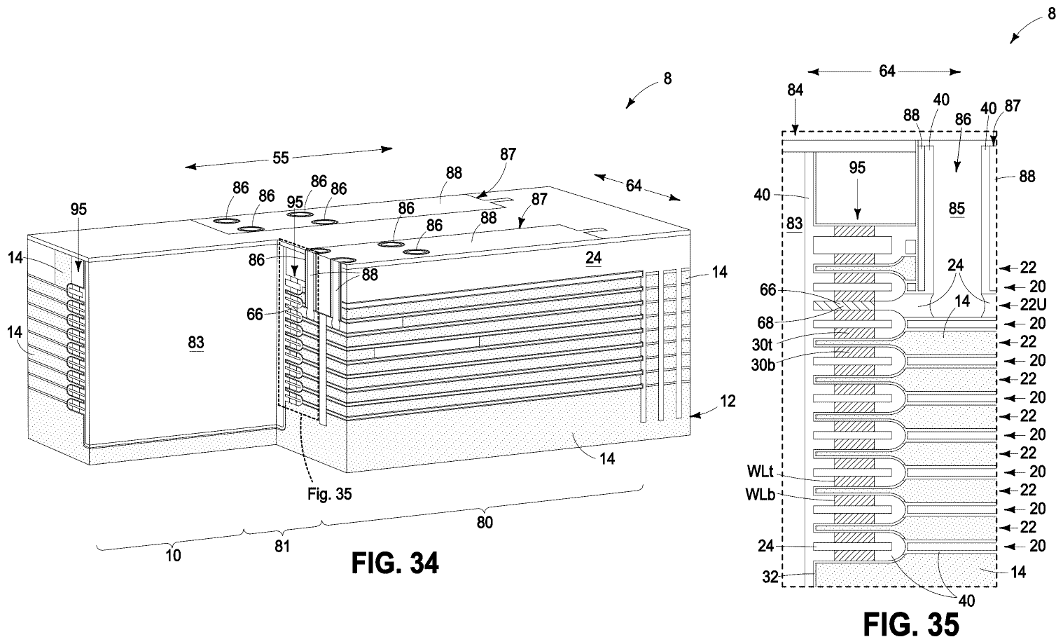

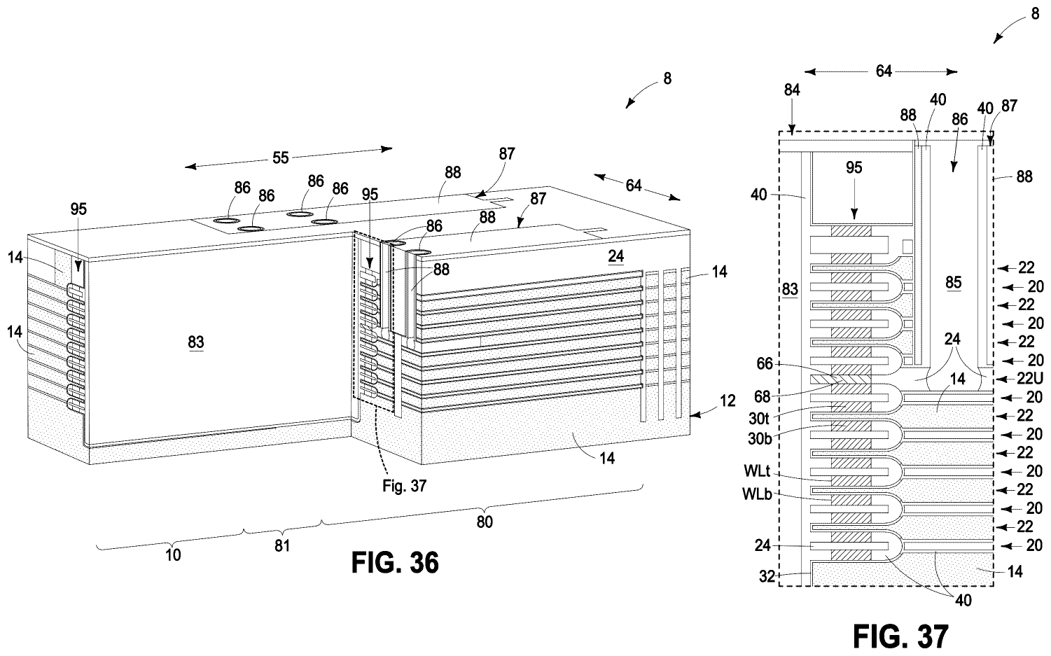

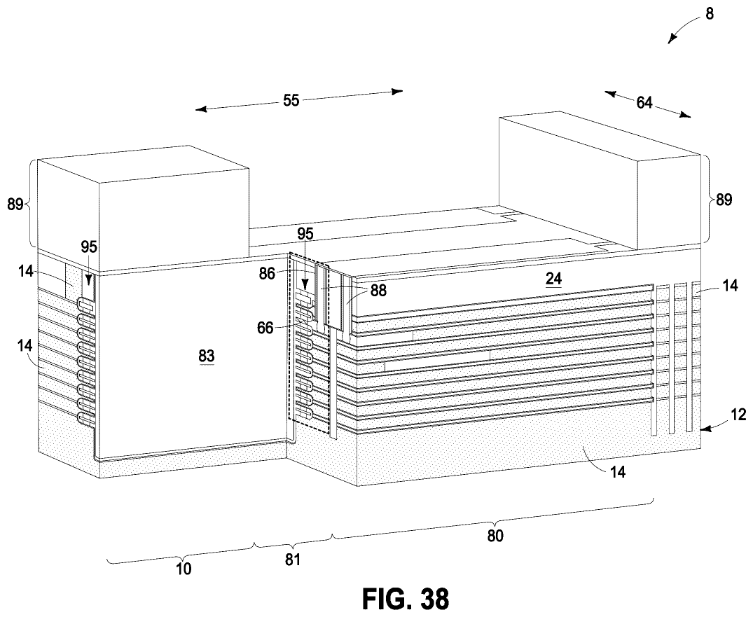

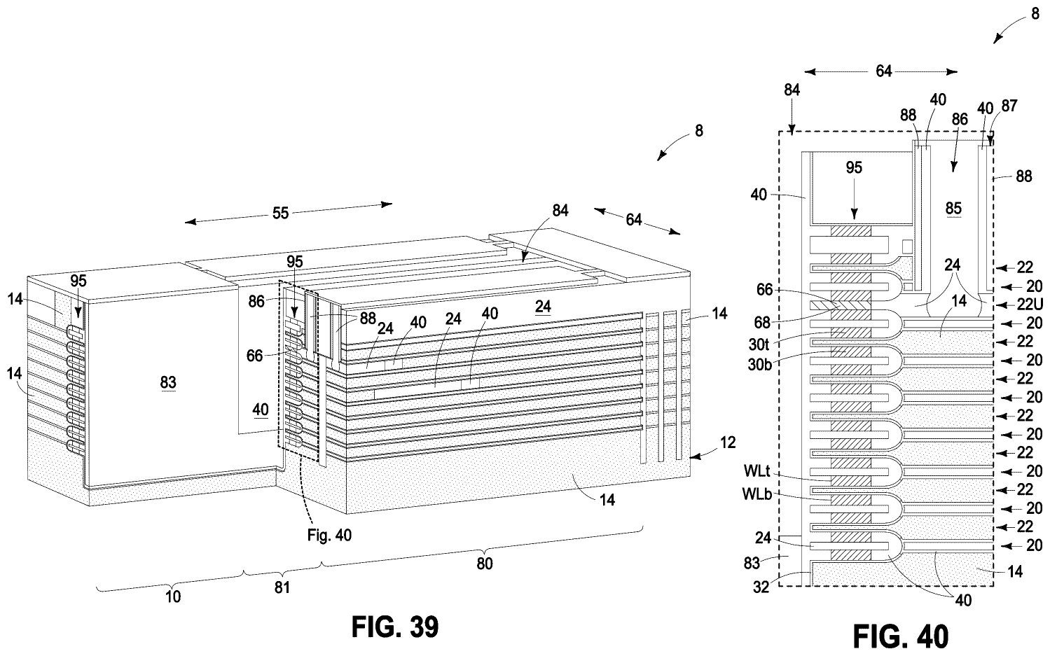

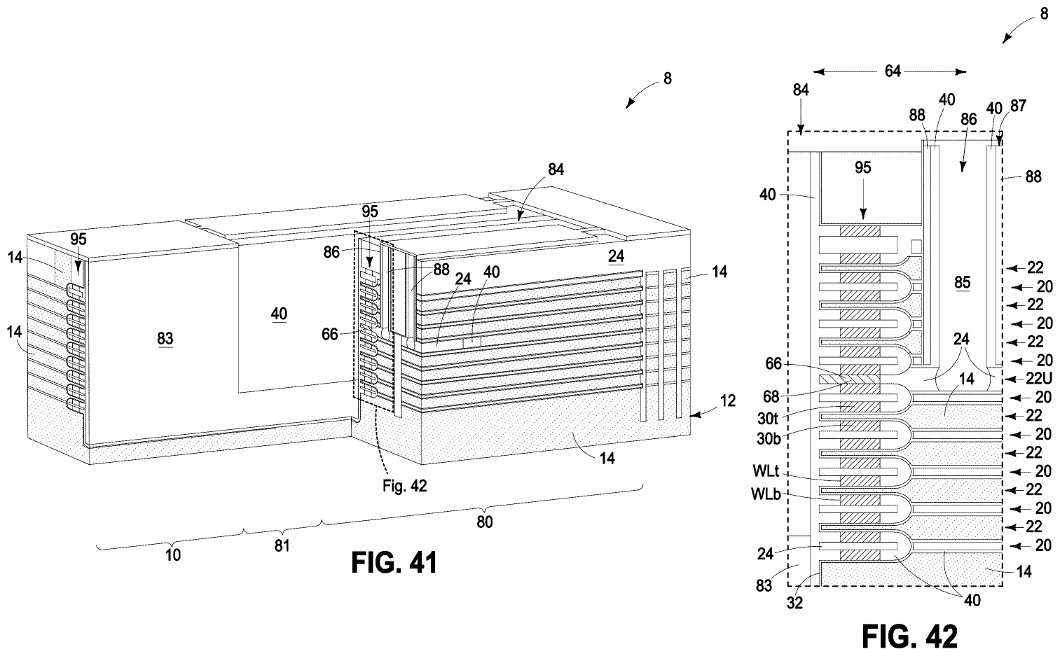

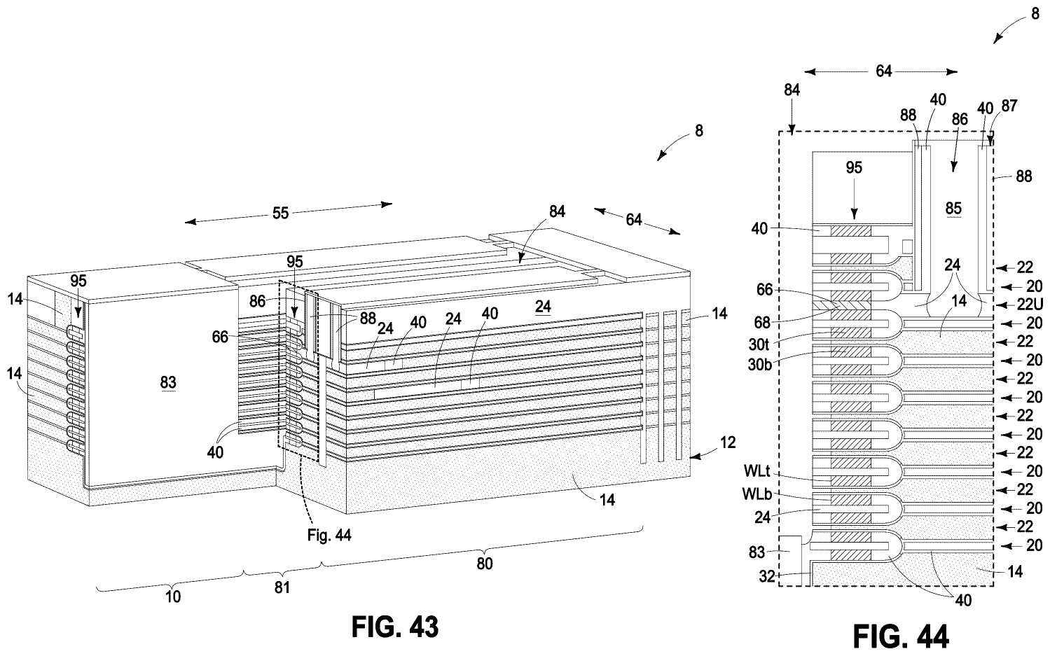

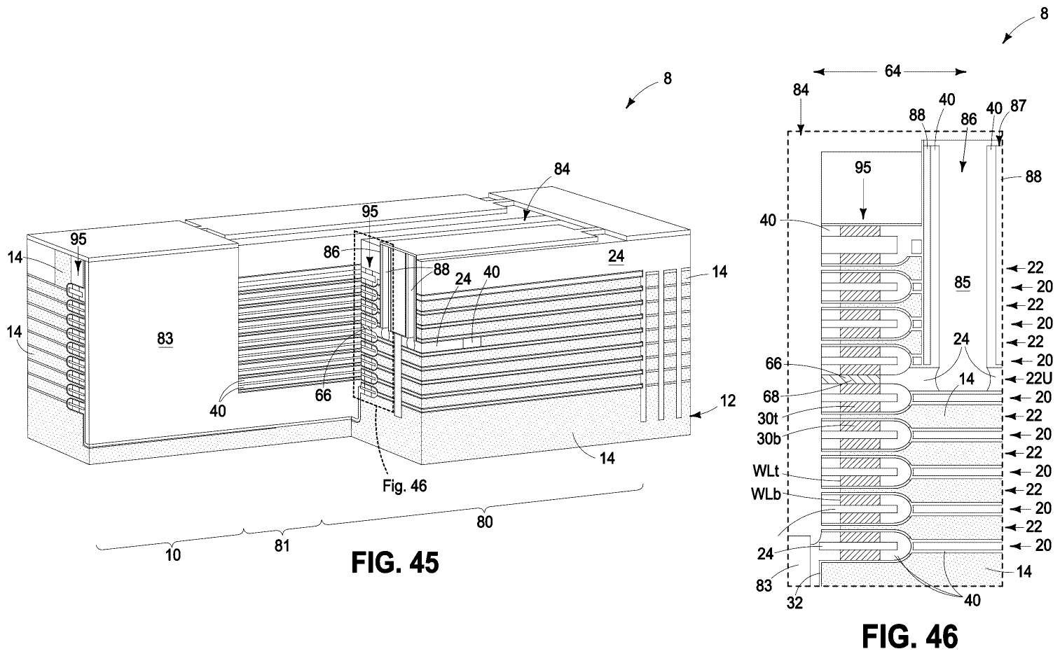

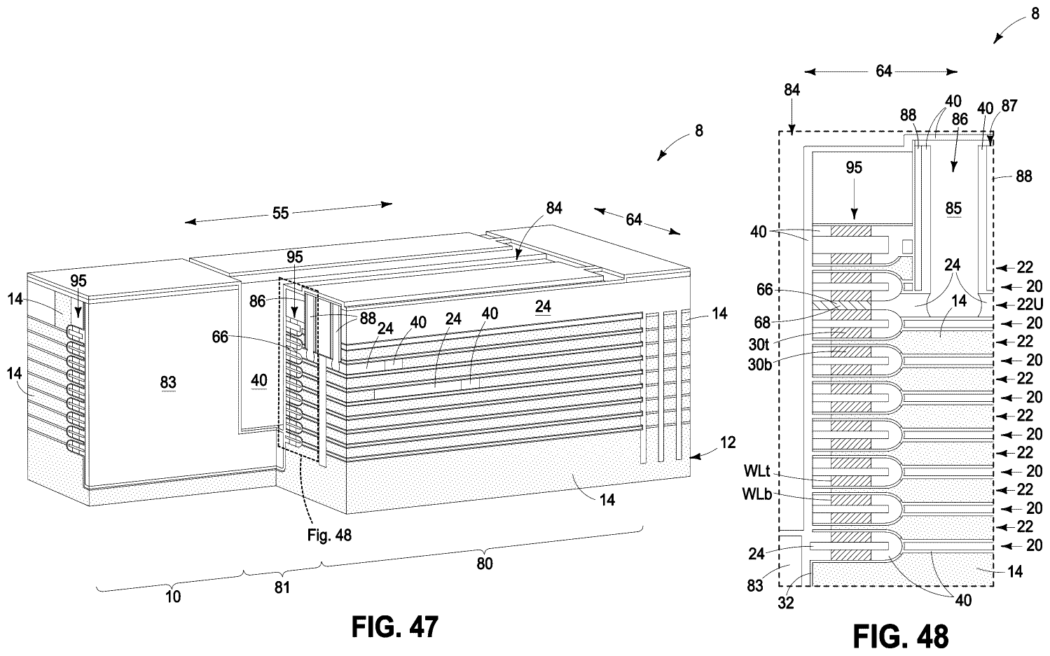

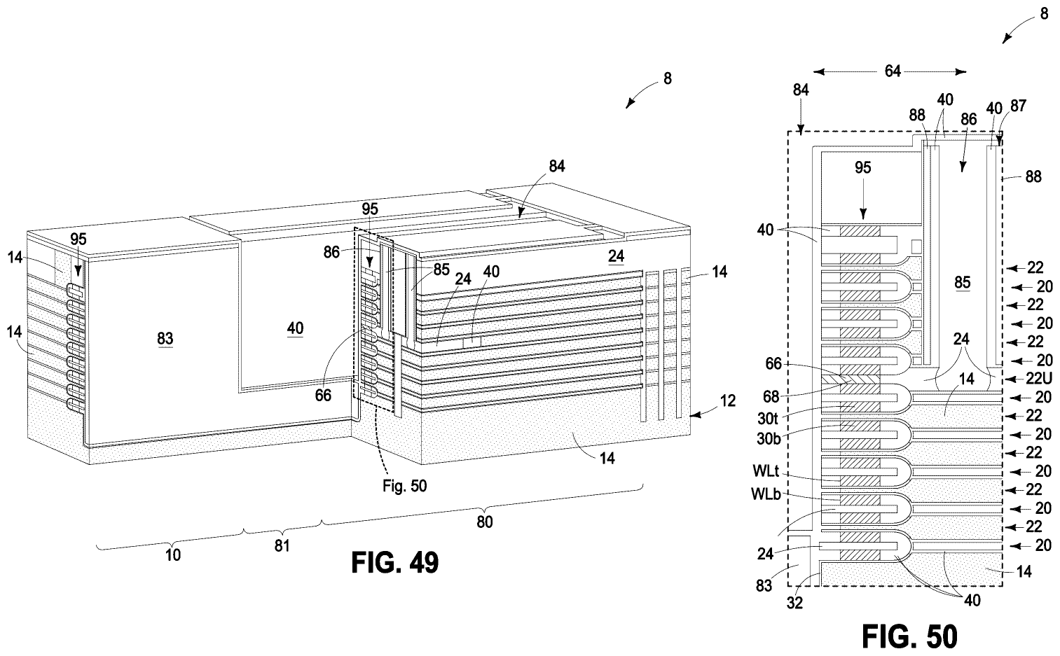

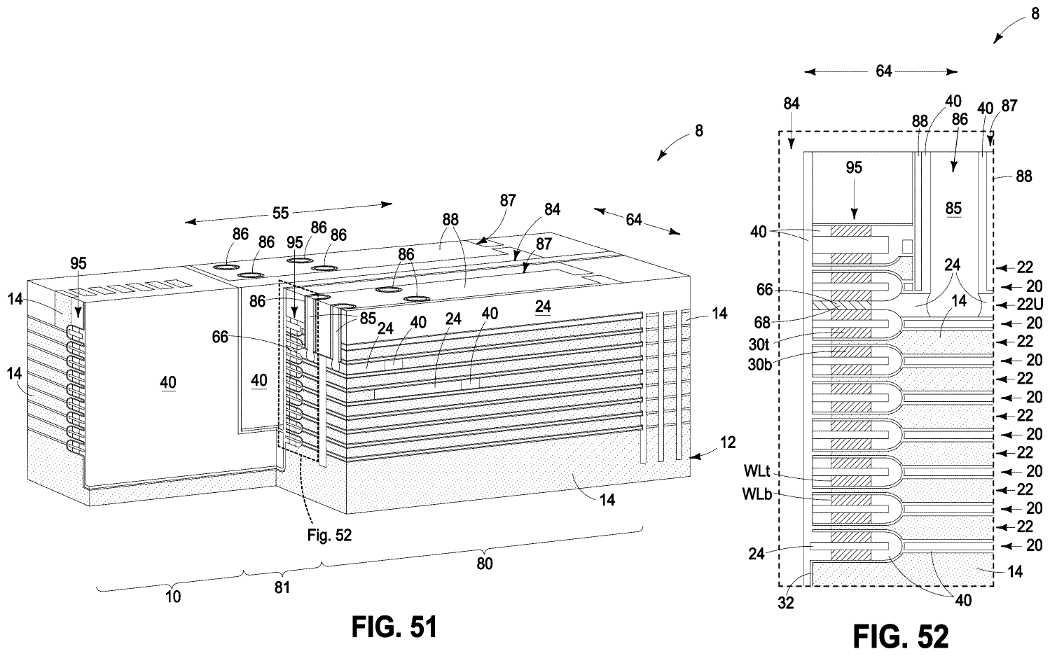

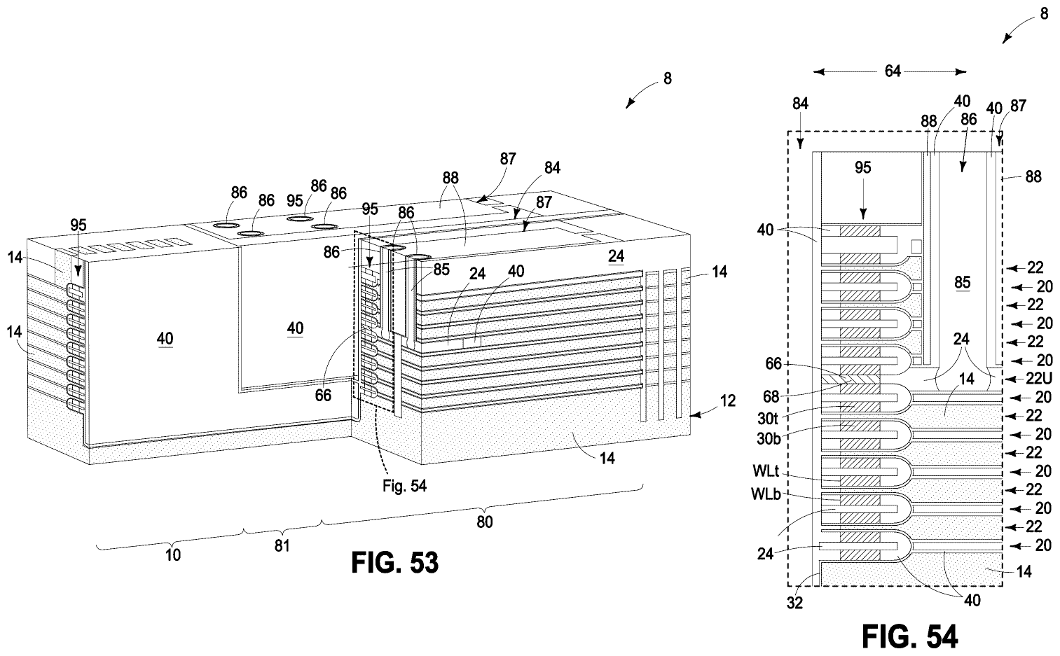

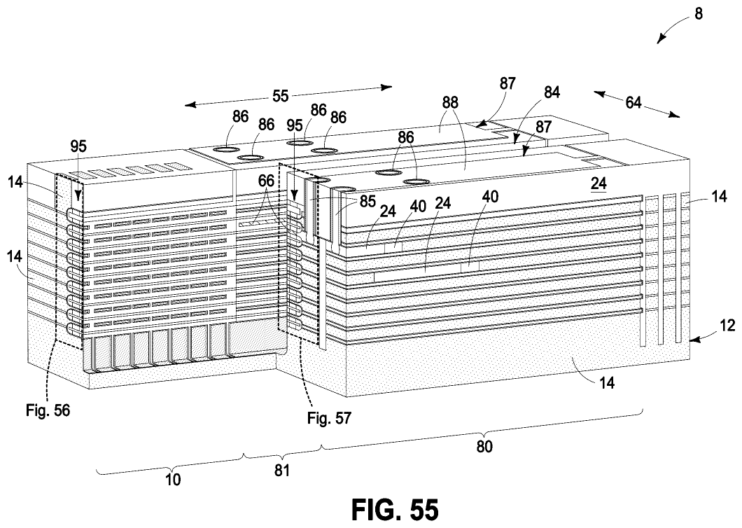

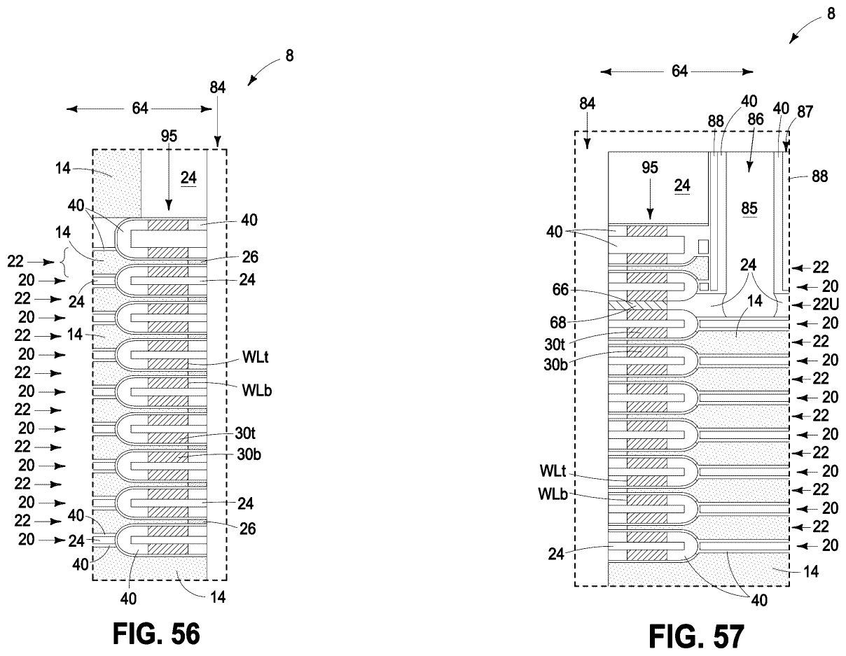

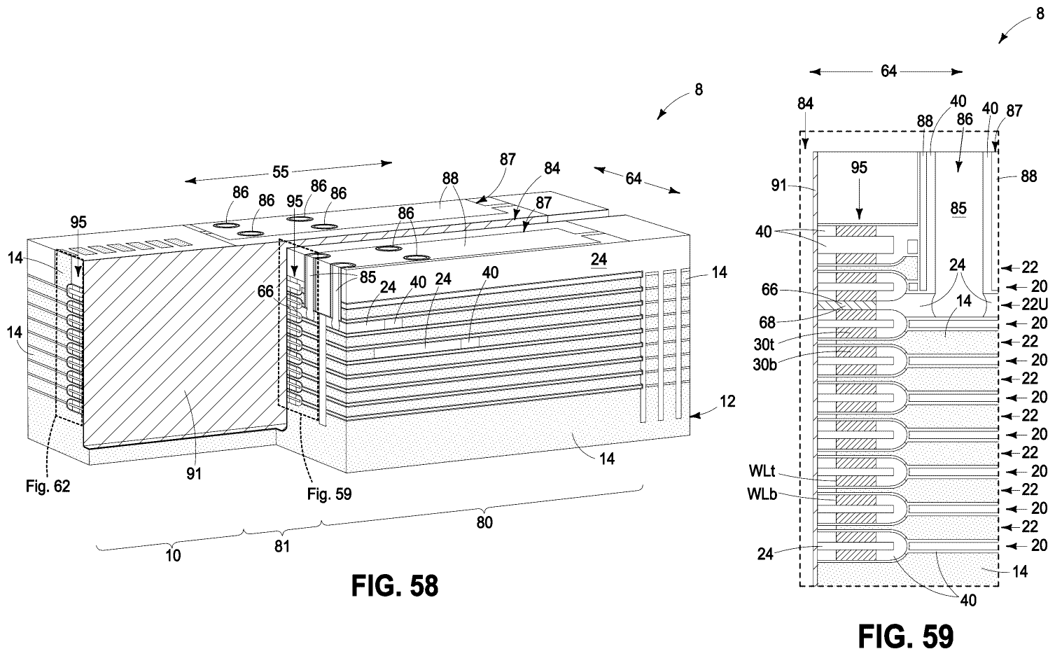

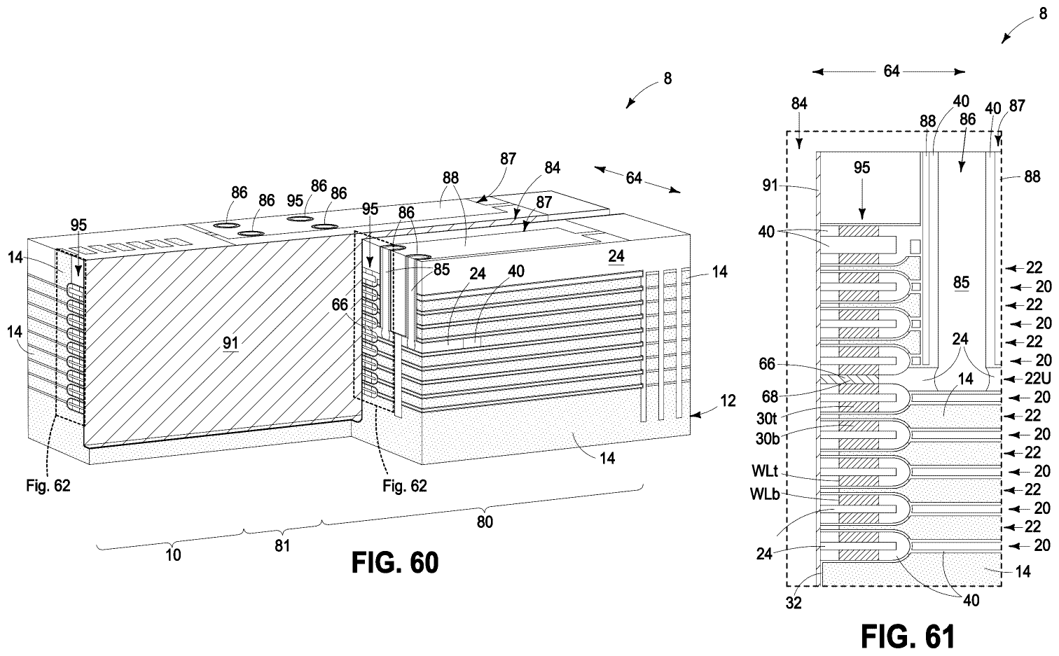

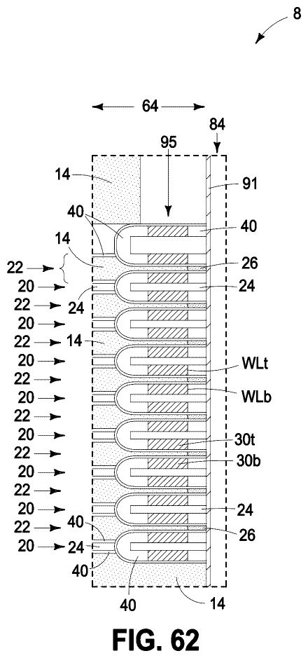

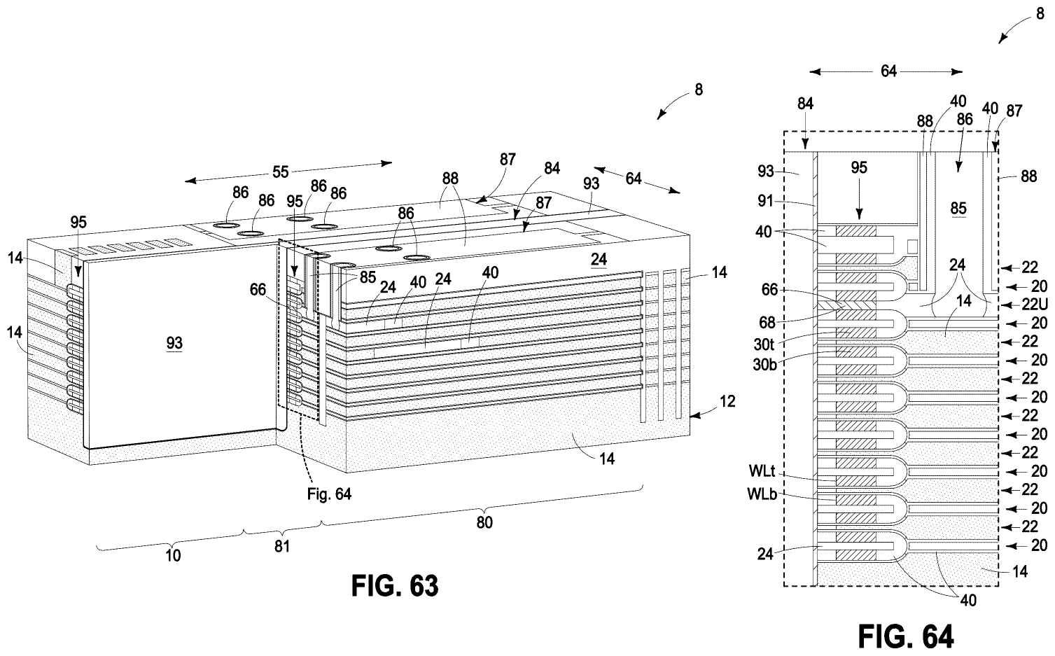

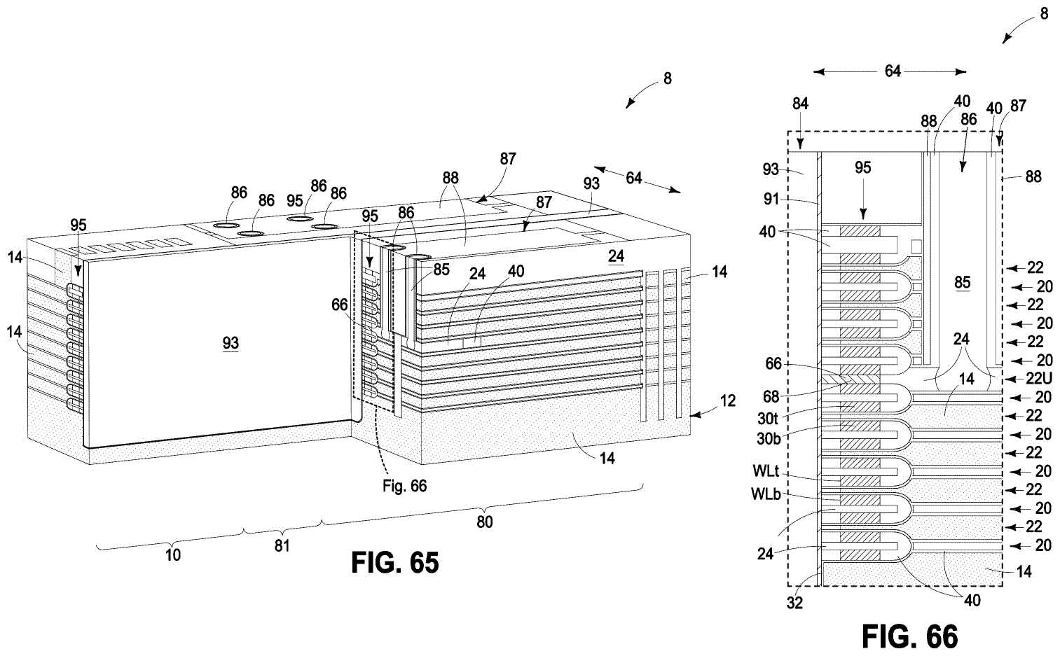

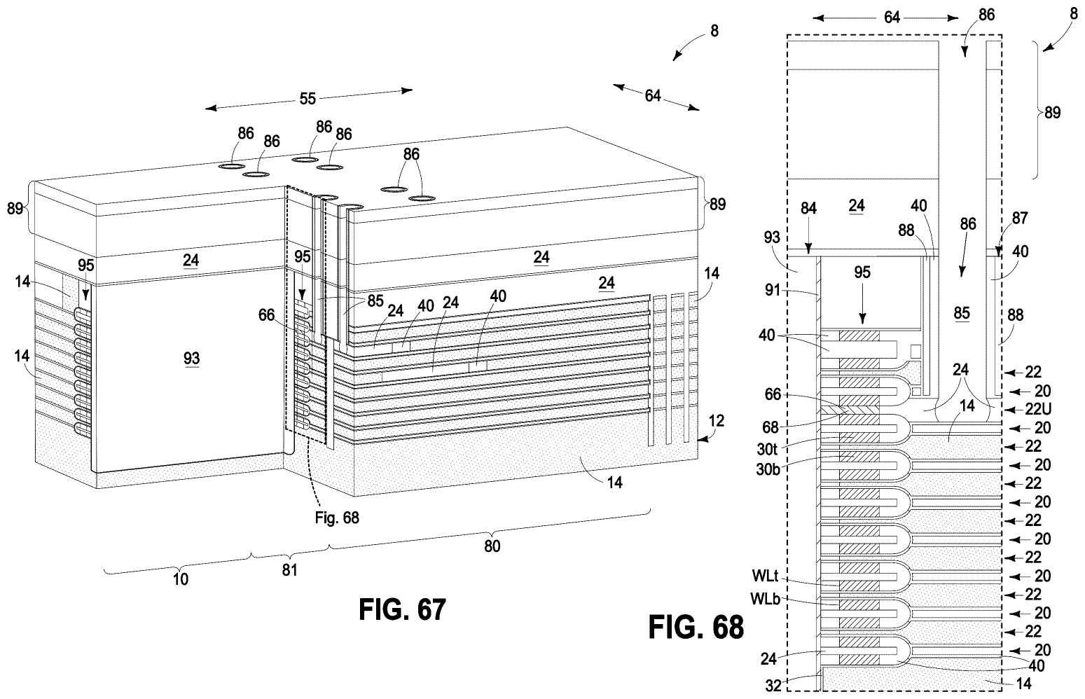

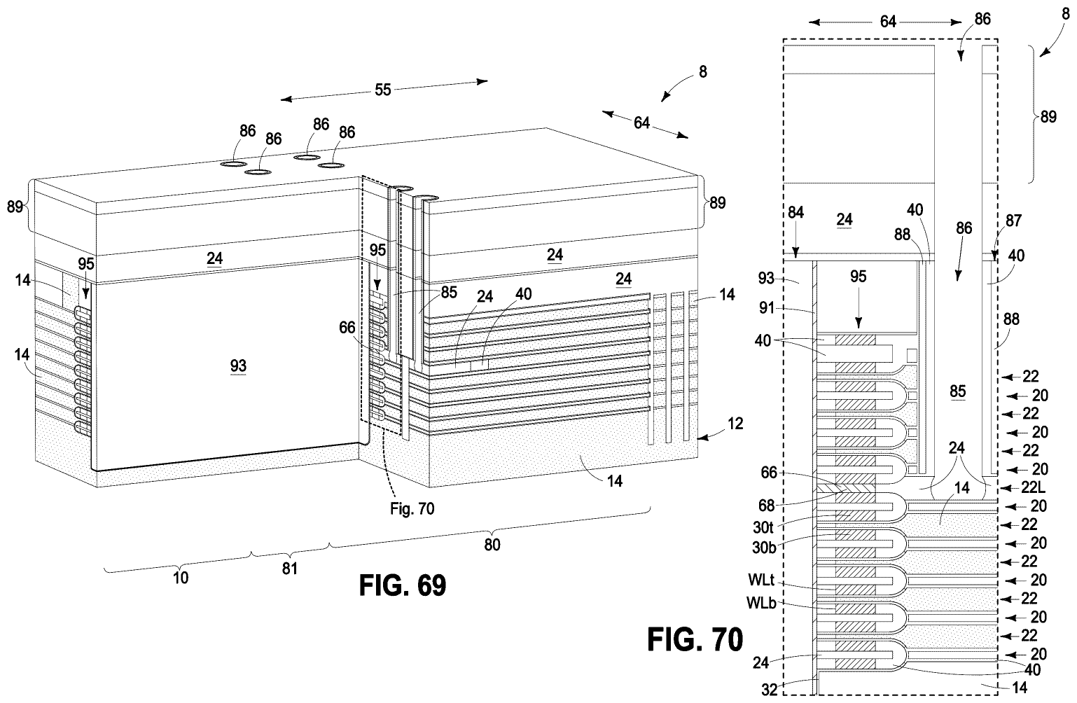

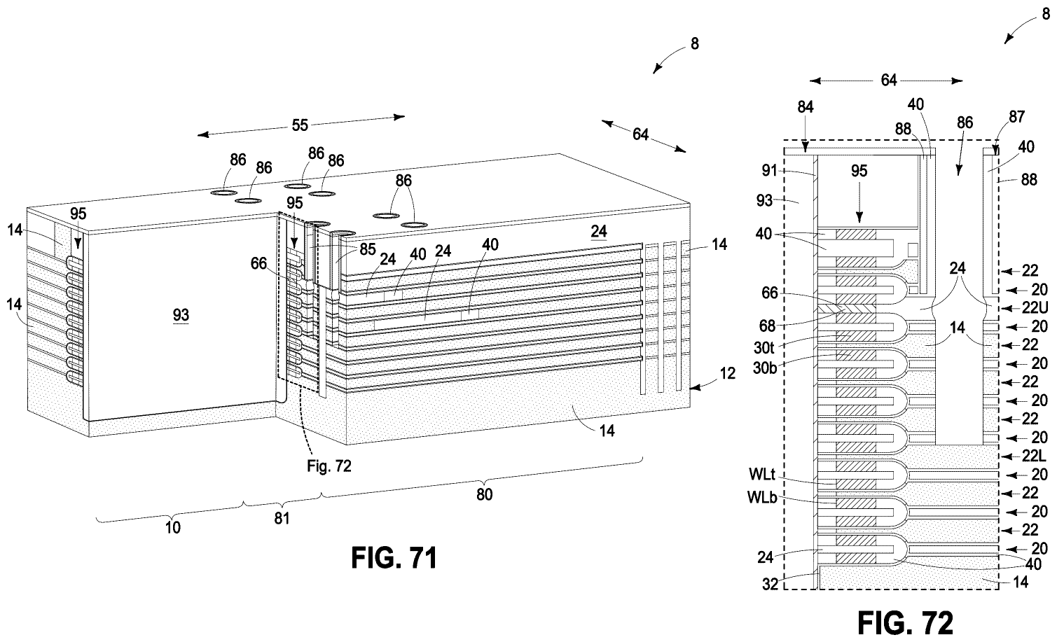

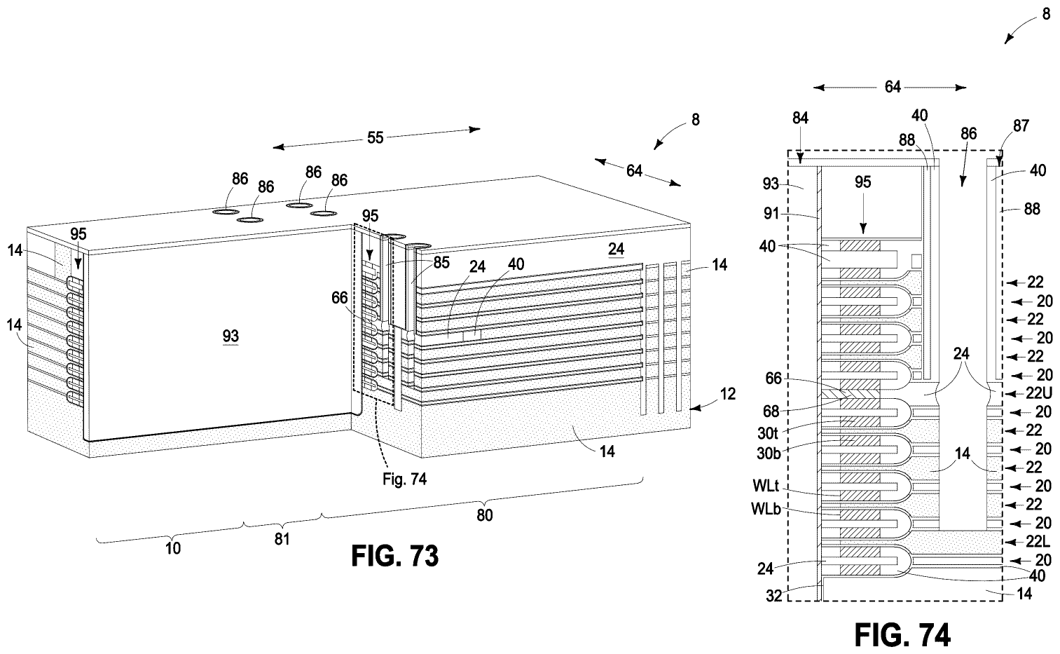

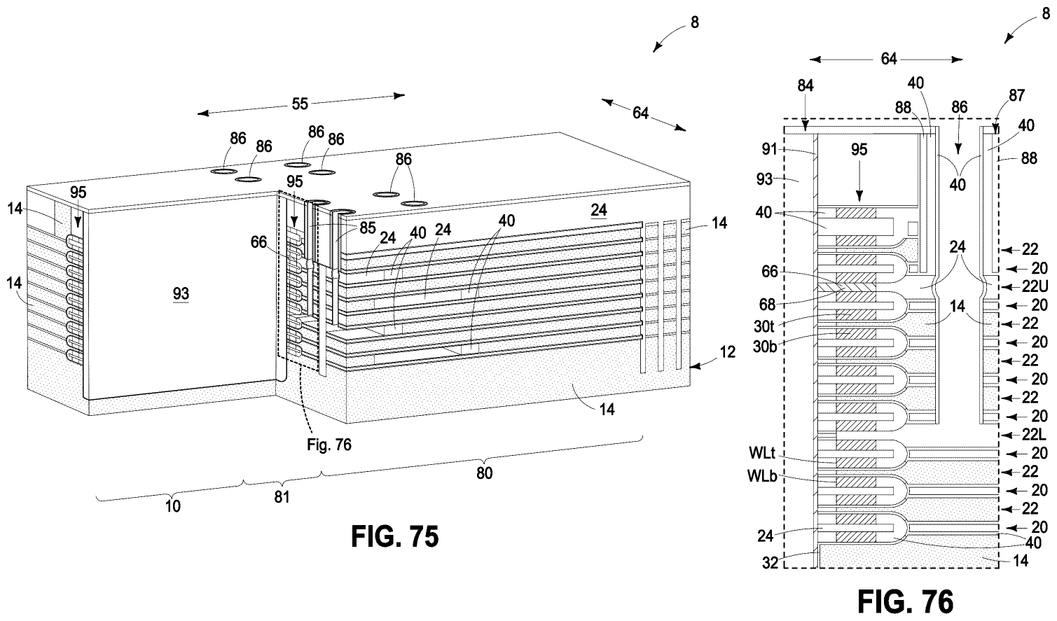

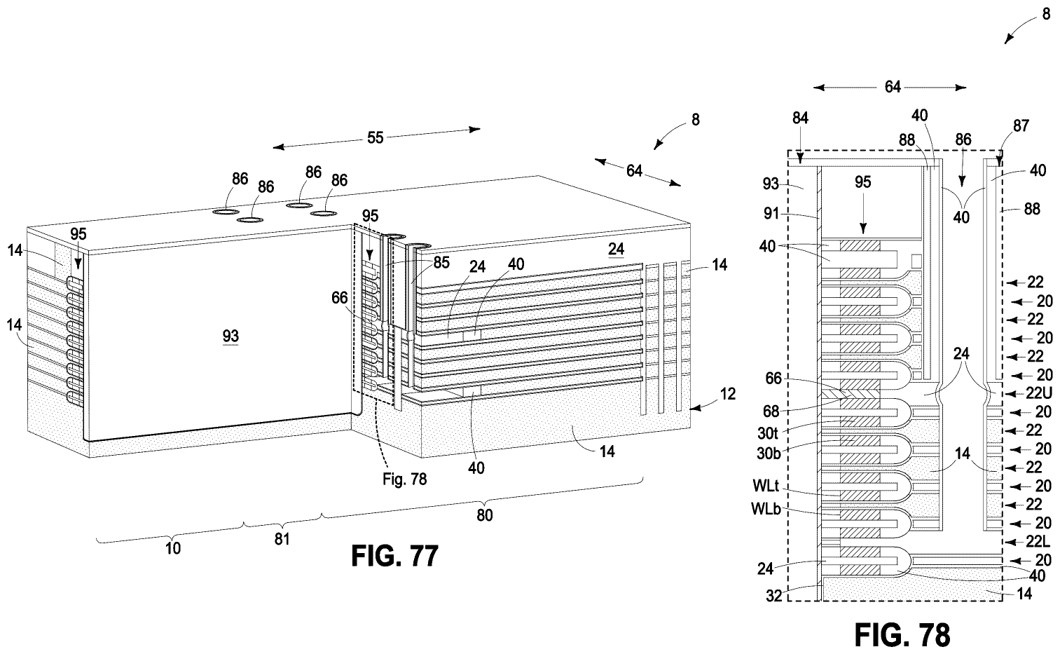

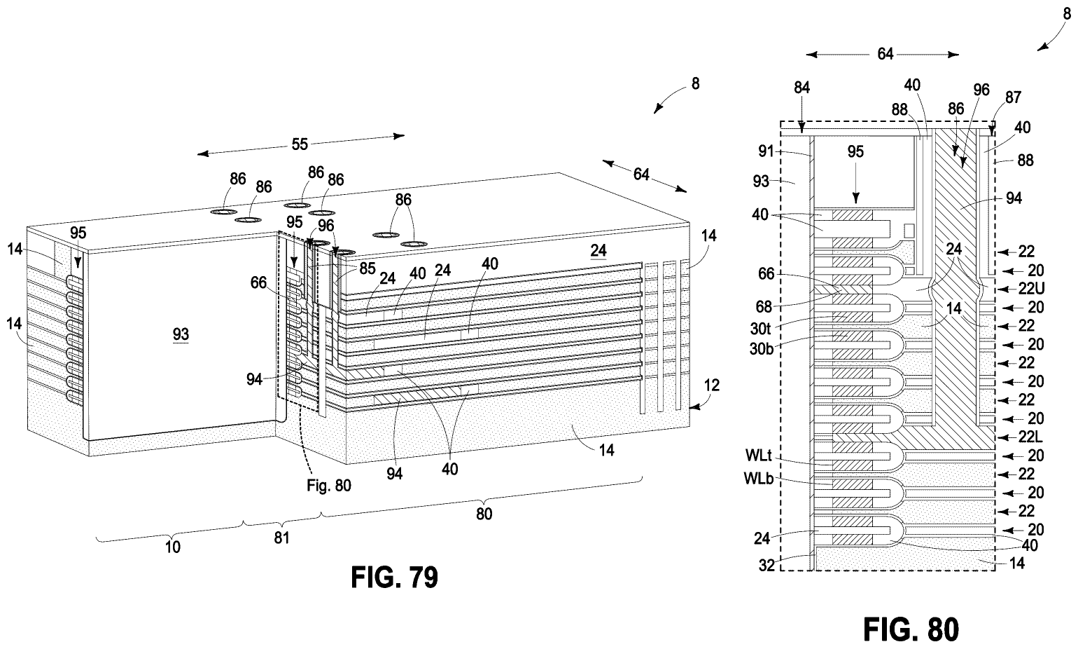

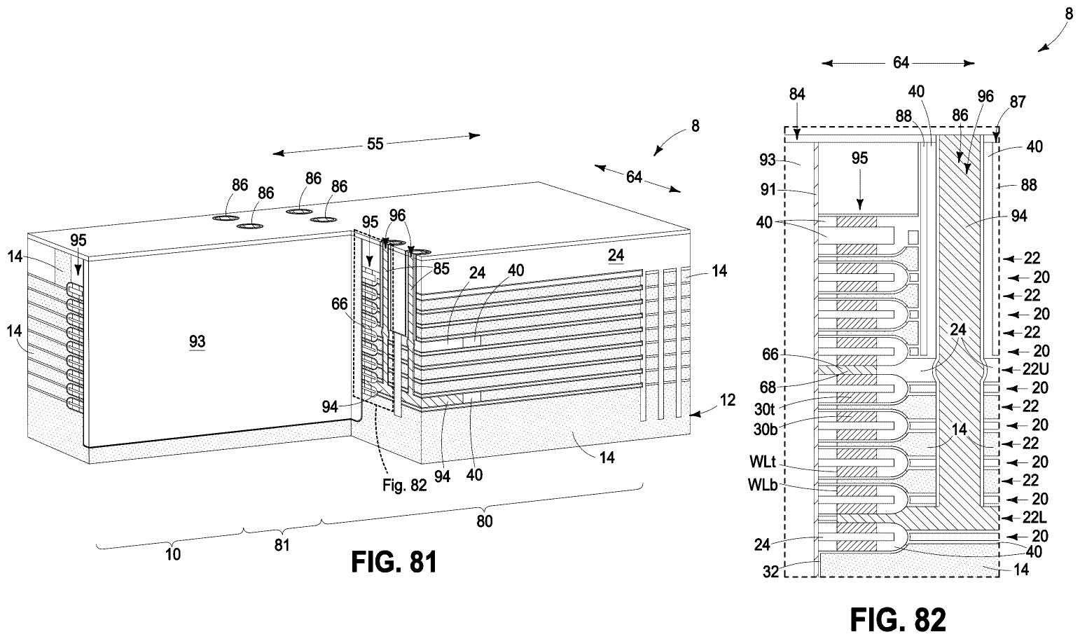

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory-array area 10 into a peripheral circuitry area 113 that is aside memory-array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory-array arca 10. Non-schematic structure embodiments as shown herein in FIGS. 3+ have the wordlines/access lines running horizontally and the digitlines/sense lines running vertically.

FIGS. 3-5 show a substrate construction 8 comprising a memory-array region 10 above a base substrate 11 (substrate 11 not shown in FIGS. 6+ for brevity) and which may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-5-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. For purposes of the continuing discussion, construction 8 may be considered as comprising a first direction 55 and a second direction 64 that are orthogonal relative one another. Example construction 8 comprises a semiconductor substrate 12 (e.g., a bulk wafer comprising monocrystalline silicon 14 and which may comprise an upper portion of substrate 11).

Memory-array region 10 has been formed to comprise vertically-alternating insulative tiers 20 (e.g., comprising insulative material 24 such as silicon dioxide) and memory-cell tiers 22*, for example as shown by arrows 20 and 22*, respectively (an * being used as a suffix to be inclusive of all such same-numerically-designated structures or portions thereof that may or may not have other suffixes). Only a few tiers 20 and 22 are shown, with construction 8 likely comprising many more (e.g., dozens, hundreds, etc.). Memory cells (e.g., MC, not-yet-completed, or yet-so-designated) in memory-cell tiers 22* comprise a horizontal transistor (e.g., T, not-yet-completed, or yet-so-designated) comprising a gate 30* and channel material 14 that is operatively-proximate gate 30 *. Channel material 14 comprises semiconductor material and portions of which will comprise conductively-doped source/drain-region material of horizontal transistors T being formed as is described below. Channel material 14 is indicated with the same numeral as material 14 of semiconductor substrate 12 although different semiconductor composition(s) therefrom may be used.

Gate 30* comprises part of one of a plurality of horizontal conductive access lines WL* that individually directly electrically couple together multiple of gates 30* of different ones of the horizontal transistors that are (will be) in the same memory-cell tier 22*. In one embodiment and as shown, individual of access lines WL* comprise a top access line WLt and a bottom access line WLb, with gate 30* comprising a top gate 30t that is part of top access line WLt and comprising a bottom gate 30b that is part of bottom access line WLb. Access lines WL* (e.g., top access lines WLt and bottom access lines WLb) in different ones of memory-cell tiers 22* are in a vertical stack 95. For brevity and clarity, only two vertical stacks 95 are shown and only one is referred to below although multiple more such stacks that are laterally spaced relative one another in second direction 64 would be included and subject to processing as described below. Regardless, access lines WL* in different ones of memory-cell tiers 22* in vertical stack 95 laterally overlap one another in second direction 64. By way of example only, access lines WL* are shown as having perfectly laterally-coincident second-direction edges and the same second-direction widths relative one another. Regardless, access lines WL*, vertical stack 95, and channel material 14 extend horizontally along first direction 55 from memory-array region 10 into a connection region 80. A buffer region 81 may be between connection region 80 and memory-array region 10 (e.g., where no operative memory cells are therein). Another buffer region 81 (not shown) and another connection region 80 (not shown) may be on the opposite first-direction side of depicted memory-array region 10 (to the right in FIG. 3). Regardless, example construction 8 is shown as also comprising additional insulative material 24, insulator material 40 (e.g., silicon nitride), and gate insulator 32 (e.g., silicon dioxide, hafnium oxide, silicon nitride, etc.). A horizontally-elongated trench 84 has been formed between vertical stacks 95 to extend from memory-array region 10 through buffer region 81 into connection region 80 and filled with a sacrificial material 83 (e.g., carbon or some other material). In some embodiments, trench 84 may be considered as a second opening 84, with a first opening 86 being referred to below and not-yet-shown.

Connection region 80 may be fabricated to comprise cavities that are laterally spaced in the first direction and in which staircase structures are fabricated, for example to have opposing flights of stairs in a stadium-like structure. Such individual stairs may comprise a tread and a riser comprising one of the memory-cell tiers for making separate electrical connection with the access lines that are in different memory-cell tiers. If so, such may be fabricated, for example, after the processing shown by FIGS. 1-5. Alternately, no such staircase structures may be fabricated (e.g., a “staircase-less” structure).

Referring to FIGS. 6-9, an example cavity 87 has optionally been formed, and which may comprise a staircase structure, and then subsequently filled with insulative material 88 (e.g., spin-on-glass). Thereafter, photoresist and hard-masking materials 89 have been formed and first openings 86 formed there-through in connection region 80 where some conductive-via constructions will first in part be fabricated to electrically couple with individual of access lines WL*. Individual first openings 86 are on one second-direction side of individual vertical stacks 95. First openings 86 that are in in a single straight-line vertical cross-section in second direction 64 may be considered as a being in a set, for example the left-four first openings 86 that are aligned in second direction 64 constituting one set and the right-four first openings 86 that are aligned in second direction 64 constituting another set that is laterally spaced from the first set in first direction 55. FIGS. 6-9 and those thereafter show processing of first openings 86 in both such sets, although for simplicity and clarity the following text is largely with respect to processing associated with a single first opening 86 in one of such sets and with respect to a single second opening 84.

FIGS. 10-13 show extending of first opening 86 into insulative material 88 followed by removal of materials 89 (no longer shown). First opening 86 extends to an upper target tier 22U which is one of memory-cell tiers 22* (or extends to thin insulator layer 40 that is immediately directly above upper target tier 22U). Individual upper target tiers 22U in FIGS. 10-13, by way of examples only, are shown as being the second tier 22* from the top in FIGS. 10 and 11 and the fourth from the top in FIGS. 12 and 13. Connection region 80 would likely be considerably longer in first direction 55 (and wider in second direction 64) than shown, having multiple cavities 87 spaced along first direction 55, but is abbreviated in the figures due to scale. Further, as stated above, no staircase structures may be formed and, if not, separate etchings may be conducted for different sets of first openings 86 to get each first opening 86 to the correct upper target tier.

Referring to FIGS. 14-17, insulator material 40 has been formed to line first opening 86 and then punch-etched to expose channel material 14 in upper target tier 22U. FIGS. 18-21 show removing channel material 14 and gate insulator 32 from upper target tier 22U through first opening 86 (e.g., using tetramethylammonium hydroxide if channel material 14 is silicon and using HF if gate insulator 32 is silicon dioxide).

Referring to FIGS. 22-25, first conductive material 66 (e.g., conductive metal material) has been formed in first opening 86 to be directly against one of access lines WL* in upper target tier 22U. In one embodiment and as shown, first conductive material 66 has been formed to comprise a conductive part 68 that is vertically between and directly electrically coupled to individual top access lines WLt and bottom access lines WLb that are in the same memory-cell tier (e.g., upper target tier 22U). FIGS. 26-29 show example lateral recessing of first conductive material 66 back from the original lateral outline of first opening 86 (e.g., by isotropic etching) in upper target tier 22U. For simplicity, such etching-back is shown as having been to align the depicted right lateral edge of conductive part 68 perfectly with such edges of the top and bottom access lines, although this would likely not be so. Rather, such etching might terminate the example right edge of conductive part 68 to the right of the top and bottom access line right edges but to the left of the lateral outline of original first opening 86. Alternately, the lateral edge of conductive part 68 might be to the left of the right edges of the top and bottom access lines such that some conductive part 68 remains vertically between the top and bottom access lines to electrically short such together.

Regardless, the processing depicted by FIGS. 10-29 is but one example showing the replacing of channel material 14 in an upper target tier 22U with first conductive material 66 that is directly against one of access lines WL* in upper target tier 22U in vertical stack 95 in connection region 80, all such replacing being conducted through a first opening 86 that is in connection region 80 on one second-direction side of vertical stack 95.

Referring to FIGS. 30-33, insulative material 24 has been formed through first opening 86 against laterally-recessed first conductive material 66. For example, such insulative material 24 may be formed to line or fill first opening 86 followed by etching such back to at least leave some of insulative material 24 laterally over laterally-recessed first conductive material 66. FIGS. 34-37 show example processing wherein first opening 86 is filled with some sacrificial material 85 (e.g., carbon or other material; e.g., yet ideally of different composition from that of sacrificial material 83).

Referring to FIG. 38, example masking material 89 has been formed to cover construction 8 but for connection region 80. FIGS. 39-42 show removal of sacrificial material 83 from trench/second opening 84 in connection region 80 (at least some of sacrificial material 83 is shown as being removed and selectively relative to other exposed materials), followed by removal of masking material 89 (no longer shown).

Referring to FIGS. 43-46, several example processing steps have occurred. First, insulator material 40 that is completely vertically along sidewalls of trench/second opening 84 has been laterally recessed to expose gate insulator oxide 32 in memory-cell tiers 22 *. Then, exposed gate insulator 32 that was over the ends of semiconductor/channel material 14 has been etched to expose such, followed by laterally etching such back as shown. Such example etching of semiconductor/channel material 14 is for simplicity shown as being exactly to the left edges of access lines WL*/gates 30*, although such etching would more likely be somewhere to the left or right of such depicted edges. Such example shown and described etchings are conducted selectively relative to first conductive material 66/conductive part 68. FIGS. 47-50 show formation of more insulator material 40 within trench/second opening 84 against laterally-recessed semiconductor/channel material 14. FIGS. 51-54 show punch etching of insulator material 40 followed by stripping of all remaining sacrificial material 83.

Referring to FIGS. 55-57, several processing steps have occurred. Within memory-array region 10, insulator material 40 that was lining trench/second opening 84 has been laterally recessed to expose gate insulator 32. As shown, such also occurs in connection region 80. Then, exposed gate insulator 32 in memory-array region 10 that was over the ends of semiconductor/channel material 14 has been laterally recessed to expose such. Such has then been conductively-doped through trench/second opening 84 (e.g., by gas phase diffusion) to form a conductively-doped source/drain region (e.g., 26) of the horizontal transistors of the memory cells being formed.

Referring to FIGS. 58-62, conducting material 91 (e.g., conductive metal material) of a first conductive-via construction (not-yet-completed and not-yet-designated) is formed to be directly electrically coupled with first conductive material 66 in upper target tier 22U in second opening 84 in connection region 80 (which is on another second-direction side of vertical stack 95 that is opposite to the one second-direction side on which first opening 86 is formed). Further, in one embodiment and as shown, conducting material 91 is formed in second opening 84 also in memory-array region 10 (e.g., directly against conductively-doped source/drain region 26). FIGS. 63-66 show example filling of remaining volume of second opening 84 with masking material 93 (e.g., undoped polysilicon).

Referring to FIGS. 67-70, more insulative material 24 and hard-masking material 89 has been deposited and patterned to form more first openings 86 there-through to previously-formed first openings 86 and sacrificial material 85 therein. FIGS. 71-74 show removal of sacrificial material 85 (no longer shown) from first opening 86, followed by extending first opening 86 vertically downward (e.g., by anisotropic etching) to a lower target tier 22L that is another one of memory-cell tiers 22* that is below upper target tier 22U. Masking material 89 (no longer shown) has also been removed before or at some point in such processing.

Referring to FIG. 75-78, several processing steps have occurred. More insulator material 40 has been deposited into extended first opening 86. Such has then been punched-etched at its bottom to expose channel material 14 in lower target tier 22L, with such channel material 14 thereafter having been removed (c.g., by isotropic etching and thereby no longer being shown) to expose gate insulator 32 in lower target tier 22L, then followed by removal thereof (e.g., by isotropic etching). Conductive material of gates 30* and access lines WL* have thereby been exposed. FIGS. 79-82 show the forming of second conductive material 94 (e.g., conductive metal material which may be the same composition as that of first conductive material 66). Thereby, a second conductive-via construction 96 has been formed in extended first opening 86 directly against one of access lines WL* (e.g., WLt and WLb) in lower target tier 22L in vertical stack 95 in connection region 80. FIGS. 73-82 show but one example of, through the extended first opening, replacing the channel material in the lower target tier with second conductive material of a second conductive-via construction that is in the extended first opening directly against one of the access lines in the lower target tier in the vertical stack in the connection region.

Referring to FIGS. 83-86, more insulative material 24 and more hard-masking material 89 have been formed, with openings 97 having then been formed over trench/second opening 84 in connection region 80 and in one embodiment in memory-array region 10 in locations between which the first conductive-via constructions and the digitlines will be formed (neither being completely-yet-constructed and thereby not yet being numerically designated). FIGS. 87-90 show extending of openings 97 into insulative material 24 and masking material 93, followed by removal of hard-masking material 89 (no longer shown).

Subsequent processing is next shown by FIGS. 91-96. As will be apparent, FIG. 96 is a not a literal vertical cross-section view taken through lines 96-96 in FIGS. 91-95. Rather, it is a perspective view with its front-depicted face being taken through or from lines 96-96 in FIGS. 91-95 (taken from just behind masking material 93 yet in/through conducting material 91). FIGS. 91-96 show remaining masking material 93 as having been used as a mask while isotropically wet etching second conductive material 94, followed by removal of insulative material 24 from atop construction 8 (such thereby no longer being shown). Such thereby forms digitlines DL (behind masking material 93) and first conductive-via constructions 65 (behind masking material 93). First and second conductive-via constructions 65, 96 are in a single straight-line vertical cross-section in second direction 64 on the one and the another second-direction sides of vertical stack 95 (e.g., such single straight-line vertical cross-section being that of either FIG. 92 or FIG. 94).

In one embodiment, and as shown and described, FIGS. 83-96 show simultaneously patterning of first conductive material 66 in second opening 84 in memory-array region 10 and in connection region 80 to form digitlines DL in memory-array region 10 and first conductive-via constructions 65 in connection region 80.

FIGS. 97-102 show formation of more insulative material 24 to cap, seal, and form void-spaces 98 (e.g., airgaps) therebelow that are between patterned masking material 93. Alternately, and by way of example only, masking material 93 may be removed (not shown), with remaining volume of trench/second opening 84 filled with insulative material 24 (not shown). Regardless, first and second conductive-via constructions 65 and 96 would connect with other circuitry above construction 8 and is not material to the inventions disclosed herein.

Referring to FIGS. 2 and 103-107, subsequent processing has been conducted in memory-array region 10 to form construction/memory circuitry 8 to comprise memory cells MC. For example, remaining semiconductor material 14 and other materials having been removed on the left side of stack 95 in memory-array region 10 in FIG. 104. Capacitors C have then been formed and that are electrically coupled with individual horizontal transistors T. Digitlines DL are electrically coupled with individual horizontal transistors T on the right side of stack 95. Capacitors C, digitlines DL, first conductive-via construction 65, and/or second conductive-via constructions 96 may be formed in any order relative one another.

Individual horizontal transistors T comprise a first source/drain region 23 (e.g., formed by conductively doping material 14 on the depicted left side of stack 95), a second source/drain region 26 (e.g., formed by conductively doping material 14 from the depicted right side of stack 95 before forming material 91 of digitlines DL), and a channel region 28, 14 horizontally between first and second source/drain regions 23 and 26. Regions 23, 26, and 28 of different immediately-horizontally-adjacent memory cells MC into and out of the plane of the page upon which FIG. 104 lies in a common memory-cell tier 22 may be isolated relative one another by insulative material (not shown). Horizontal transistors T also individually comprise gate 30* (e.g., gate-all-around the channel) having gate insulator 32 (e.g., dielectric or ferroelectric) between at least channel region 28 and gate 30*. An example insulator material (e.g., 40) is laterally against lateral sides/edges of gates 30* on the depicted right side of stack 95.

Example capacitors C individually comprises a first capacitor electrode 33 (e.g., a storage-node electrode), a second capacitor electrode 34 (e.g., comprising conductive metal material 70 and conductively-doped polysilicon 71), and a capacitor insulator 36 there-between (e.g., dielectric or ferroelectric). Example second capacitor electrodes 34 of multiple capacitors C are directly electrically coupled with one another. Example first capacitor electrode 33 is directly coupled to first source/drain region 23 of horizontal transistor T. Digitlines DL extend through vertically-alternating tiers 20 and 22. Individual second source/drain regions 26 of individual transistors T that are in different memory-cell tiers 22 are directly electrically coupled to individual digitlines DL. Void-space 98 and/or solid insulative material is between immediately-adjacent digitlines DL.

Any other attribute(s) or aspect(s) as shown and/or described herein with respect to other embodiments may be used with respect to the above embodiments.

In one embodiment, a method used in forming memory circuitry (e.g., 8) comprising memory cells (e.g., MC) comprises forming vertically-alternating insulative tiers (e.g., 20) and memory-cell tiers (e.g., 22). The memory cells individually comprise a horizontal transistor (e.g., T) comprising a gate (e.g., 30*). The gate comprises part of one of a plurality of horizontal conductive access lines (e.g., WL*) that individually directly electrically couple together multiple of the gates of different ones of the horizontal transistors that are in the same memory-cell tier. The access lines extend horizontally from a memory-array region (e.g., 10) into a connection region (e.g., 80). Over a same time period and using the same processing steps, digitlines (e.g., DL) and conductive-via constructions (e.g., 65) are simultaneously formed, with the digitlines being in the memory-array region and individually directly electrically coupling to the horizontal transistors in different ones of the memory-cell tiers and the conductive-via constructions being in the connection region and individually directly electrically coupling to individual of the access lines.

In one such embodiment, the digitlines and the conductive via constructions are formed to have the same minimum horizontal thickness (e.g., MHT1 in FIGS. 98, 100, and 101) relative one another, and wherein the access lines extend horizontally along a first direction (e.g., 55) from the memory-array region into a connection region (e.g., 80), with the same minimum horizontal thickness being in a second direction (e.g., 64) that is orthogonal to the first direction.

In one embodiment, the conductive-via constructions are a first set and further comprising a second set of conductive-via constructions (e.g., 96) in the connection region that individually directly electrically couple to individual of the access lines that are different from the individual access lines that the first set is directly electrically coupled to. In one such embodiment, at least a majority of the second set is formed after the same period in which the first set is formed (e.g., parts 68 being a minority volumetric portion of conductive-via constructions 96 that are fabricated before the first set is fabricated). In one embodiment, the first and second sets of conductive-via constructions have different minimum horizontal thicknesses relative one another (e.g., MHT1 and MHT2 in FIG. 98 and MHT1 and MHT2 in FIG. 100). In one such latter embodiment and as shown, the conductive-via constructions of the second set individually have larger minimum horizontal thickness (e.g., MHT2) than the conductive-via constructions of the first set (e.g., MHT1).

Any other attribute(s) or aspect(s) as shown and/or described herein with respect to other embodiments may be used.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 8) comprises a memory-array region (e.g., 10) comprising vertically-alternating insulative tiers (e.g., 20) and memory-cell tiers (e.g., 22). Memory cells (e.g., MC) in the memory-cell tiers individually comprise a horizontal transistor (e.g., T) comprising a gate (e.g., 30*). The gate comprises part of one of a plurality of horizontal conductive access lines (e.g., WL*) that individually directly electrically couple together multiple of the gates of different ones of the horizontal transistors that are in the same memory-cell tier. The access lines in different ones of the memory-cell tiers are in a vertical stack (e.g., 95) wherein the access lines in the different ones of the memory-cell tiers laterally overlap one another. The access lines and the vertical stack extend horizontally along a first direction (e.g., 55) from the memory-array region into a connection region (e.g., 80). The connection region comprises conductive-via constructions (e.g., 65, 96) that individually directly electrically couple to individual of the access lines. Individual of the conductive-via constructions comprise a vertically-elongated conductive portion (e.g., 67 in FIGS. 98 and 100) that is laterally-spaced from the vertical stack in a second direction (e.g., 64) that is orthogonal to the first direction. Two of the conductive-via constructions are in a single straight-line vertical cross-section (e.g., that of one of FIG. 98 or FIG. 100) in the second direction on opposite second-direction sides of the vertical stack. In one such embodiment, the two are a first two and further comprising a second two (e.g., 65, 96) of the conductive-via constructions in another single straight-line vertical cross-section in the second direction on the opposite second-direction sides of the vertical stack (e.g., that of the other of FIG. 98 and FIG. 100), with the first two being laterally-spaced from the second two in the first direction (e.g., as evident from FIGS. 97 and 99).

In one embodiment, the horizontal transistor comprises channel material (e.g., 14) that is operatively proximate the gate, with the channel material extending horizontally from the memory-array region into the connection region. In one such embodiment, the channel material in individual of the memory-cell tiers is vertically thickest in the connection region laterally of one of the second-direction sides of the vertical stack (e.g., the depicted right side in either of FIGS. 98 or 100). In one such latter, embodiment, the channel material in individual of the memory-cell tiers is vertically thickest in the connection region laterally of only one of the second-direction sides of the vertical stack (e.g., the depicted right side in either of FIGS. 98 or 100). In one embodiment, none of the channel material in individual of the memory-cell tiers in the connection region is laterally of the other one of the second-direction sides of the vertical stack (e.g., no channel material 14 being on the depicted left side in either of FIGS. 98 or 100).

Any other attribute(s) or aspect(s) as shown and/or described herein with respect to other embodiments may be used.

In one embodiment, memory circuitry (e.g., 8) comprises a memory-array region (e.g., 10) comprising vertically-alternating insulative tiers (e.g., 20) and memory-cell tiers (e.g., 22). Memory cells (e.g., MC) in the memory-cell tiers individually comprise a horizontal transistor (e.g., T) comprising a gate (e.g., 30*). The gate comprises part of one of a plurality of horizontal conductive access lines (e.g., WL*) that individually directly electrically couple together multiple of the gates of different ones of the horizontal transistors that are in the same memory-cell tier. Individual of the access lines comprise a top access line (e.g., WLt) and a bottom access line (e.g., WLb). The gate comprises a top gate (e.g., 30t) that is part of the top access line and comprises a bottom gate (e.g., 30b) that is part of the bottom access line. The top and bottom access lines in different ones of the memory-cell tiers are in a vertical stack (e.g., 95) wherein the top and bottom access lines in the different ones of the memory-cell tiers laterally overlap one another. The top and bottom access lines and the vertical stack extend horizontally along a first direction (e.g., 55) from the memory-array region into a connection region (e.g., 80). The connection region comprises conductive-via constructions (e.g., 96) that individually comprise a conductive part (e.g., 68) that is vertically between and directly electrically coupled to individual of the top and bottom access lines that are in the same memory-cell tier. Individual of the conductive-via constructions comprise a vertically-elongated conductive portion (e.g., 67) that is laterally-spaced from the vertical stack in a second direction (e.g., 64) that is orthogonal to the first direction. Two of the conductive-via constructions are in a single straight-line vertical cross-section in the second direction on opposite second-direction sides of the vertical stack (e.g., that of one of FIG. 98 or FIG. 100).

Any other attribute(s) or aspect(s) as shown and/or described herein with respect to other embodiments may be used.

Embodiments of the invention may enable reduction of size/volume of connection region 80 (e.g., along first direction 55) by providing multiple conductive-via constructions in the same vertical cross-section along second direction 64, thus enabling an overall increase in circuit density. Additionally, reusing the same contact hole space (first opening 86) may enable reduction of die size.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprising memory cells comprises forming vertically-alternating insulative tiers and memory-cell tiers. The memory cells individually comprise a horizontal transistor comprising a gate and channel material operatively-proximate the gate. The gate comprises part of one of a plurality of horizontal conductive access lines that individually directly electrically couple together multiple of the gates of different ones of the horizontal transistors that are in the same memory-cell tier. The access lines in different ones of the memory-cell tiers are in a vertical stack. The access lines, the vertical stack, and the channel material extend horizontally along a first direction from a memory-array region into a connection region. The access lines in the different ones of the memory-cell tiers in the vertical stack laterally overlap one another in a second direction that is orthogonal to the first direction. Through a first opening in the connection region on one second-direction side of the vertical stack, the channel material in an upper target tier that is one of the memory-cell tiers is replaced with first conductive material that is directly against one of the access lines in the upper target tier in the vertical stack in the connection region. In a second opening in the connection region on another second-direction side of the vertical stack that is opposite the one second-direction side, conducting material of a first conductive-via construction is formed and directly electrically coupled with the first conductive material in the upper target tier. The first opening is extended vertically downward to a lower target tier that is another one of the memory-cell tiers that is below the upper target tier. Through the extended first opening, the channel material in the lower target tier is replaced with second conductive material of a second conductive-via construction that is in the extended first opening directly against one of the access lines in the lower target tier in the vertical stack in the connection region. The first and second conductive-via constructions are in a single straight-line vertical cross-section in the second direction on the one and the another second-direction sides of the vertical stack.

In some embodiments, a method used in forming memory circuitry comprising memory cells comprises forming vertically-alternating insulative tiers and memory-cell tiers. The memory cells individually comprise a horizontal transistor comprising a gate. The gate comprises part of one of a plurality of horizontal conductive access lines that individually directly electrically couple together multiple of the gates of different ones of the horizontal transistors that are in the same memory-cell tier. The access lines extend horizontally from a memory-array region into a connection region. Over a same time period and using the same processing steps, digitlines are simultaneously formed in the memory-array region that individually directly electrically couple to the horizontal transistors in different ones of the memory-cell tiers and conductive-via constructions in the connection region that individually directly electrically couple to individual of the access lines.

In some embodiments, memory circuitry comprises a memory-array region comprising vertically-alternating insulative tiers and memory-cell tiers. Memory cells in the memory-cell tiers individually comprise a horizontal transistor comprising a gate. The gate comprises part of one of a plurality of horizontal conductive access lines that individually directly electrically couple together multiple of the gates of different ones of the horizontal transistors that are in the same memory-cell tier. The access lines in different ones of the memory-cell tiers are in a vertical stack wherein the access lines in the different ones of the memory-cell tiers laterally overlap one another. The access lines and the vertical stack extend horizontally along a first direction from the memory-array region into a connection region. The connection region comprises conductive-via constructions that individually directly electrically couple to individual of the access lines. Individual of the conductive-via constructions comprise a vertically-elongated conductive portion that is laterally-spaced from the vertical stack in a second direction that is orthogonal to the first direction. Two of the conductive-via constructions are in a single straight-line vertical cross-section in the second direction on opposite second-direction sides of the vertical stack.

In some embodiments, memory circuitry comprises a memory-array region comprising vertically-alternating insulative tiers and memory-cell tiers. Memory cells are in the memory-cell tiers and individually comprise a horizontal transistor comprising a gate. The gate comprises part of one of a plurality of horizontal conductive access lines that individually directly electrically couple together multiple of the gates of different ones of the horizontal transistors that are in the same memory-cell tier. Individual of the access lines comprise a top access line and a bottom access line. The gate comprises a top gate that is part of the top access line and comprises a bottom gate that is part of the bottom access line. The top and bottom access lines in different ones of the memory-cell tiers are in a vertical stack wherein the top and bottom access lines in the different ones of the memory-cell tiers laterally overlap one another. The top and bottom access lines and the vertical stack extend horizontally along a first direction from the memory-array region into a connection region. The connection region comprises conductive-via constructions that individually comprise a conductive part that is vertically between and directly electrically coupled to individual of the top and bottom access lines that are in the same memory-cell tier. Individual of the conductive-via constructions comprise a vertically-elongated conductive portion that is laterally-spaced from the vertical stack in a second direction that is orthogonal to the first direction. Two of the conductive-via constructions are in a single straight-line vertical cross-section in the second direction on opposite second-direction sides of the vertical stack.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising memory cells, comprising:
forming vertically-alternating insulative tiers and memory-cell tiers, the memory cells individually comprising a horizontal transistor comprising a gate and channel material operatively-proximate the gate, the gate comprising part of one of a plurality of horizontal conductive access lines that individually directly electrically couple together multiple of the gates of different ones of the horizontal transistors that are in the same memory-cell tier, the access lines in different ones of the memory-cell tiers being in a vertical stack; the access lines, the vertical stack, and the channel material extending horizontally along a first direction from a memory-array region into a connection region; the access lines in the different ones of the memory-cell tiers in the vertical stack laterally overlapping one another in a second direction that is orthogonal to the first direction;
through a first opening in the connection region on one second-direction side of the vertical stack, replacing the channel material in an upper target tier that is one of the memory-cell tiers with first conductive material that is directly against one of the access lines in the upper target tier in the vertical stack in the connection region;
in a second opening in the connection region on another second-direction side of the vertical stack that is opposite the one second-direction side, forming conducting material of a first conductive-via construction directly electrically coupled with the first conductive material in the upper target tier;
extending the first opening vertically downward to a lower target tier that is another one of the memory-cell tiers that is below the upper target tier; and
through the extended first opening, replacing the channel material in the lower target tier with second conductive material of a second conductive-via construction that is in the extended first opening directly against one of the access lines in the lower target tier in the vertical stack in the connection region, the first and second conductive-via constructions being in a single straight-line vertical cross-section in the second direction on the one and the another second-direction sides of the vertical stack.

2. The method of claim 1 comprising, before forming the conducting material and through the first opening:
laterally recessing the first conductive material in the upper target tier; and
forming insulative material against the laterally-recessed first conductive material.

3. The method of claim 1 comprising, before forming the conducting material and through the second opening:
laterally recessing the channel material in individual of the memory-cell tiers; and
forming insulator material against the laterally-recessed channel material.

4. The method of claim 1 comprising, before forming the conducting material, sequentially:
laterally recessing the first conductive material in the upper target tier through the first opening;
through the first opening, forming insulative material against the laterally-recessed first conductive material;
laterally recessing the channel material through the second opening in individual of the memory-cell tiers; and
through the second opening, forming insulator material against the laterally-recessed channel material.

5. The method of claim 1,
wherein the second opening extends to be within the memory-array region;
wherein the conducting material is formed in the second opening in the memory-array region; and
comprising simultaneously patterning the first conductive material in the second opening in the memory-array region and in the connection region to form digitlines in the memory-array region and the first conductive-via constructions in the connection region.

6. A method used in forming memory circuitry comprising memory cells, comprising:
forming vertically-alternating insulative tiers and memory-cell tiers, the memory cells individually comprising a horizontal transistor comprising a gate, the gate comprising part of one of a plurality of horizontal conductive access lines that individually directly electrically couple together multiple of the gates of different ones of the horizontal transistors that are in the same memory-cell tier, the access lines extending horizontally from a memory-array region into a connection region; and
over a same time period and using the same processing steps, simultaneously forming digitlines in the memory-array region that individually directly electrically couple to the horizontal transistors in different ones of the memory-cell tiers and conductive-via constructions in the connection region that individually directly electrically couple to individual of the access lines.

7. The method of claim 6 comprising forming the digitlines and the conductive via constructions to have the same minimum horizontal thickness relative one another.

8. The method of claim 7 wherein the access lines extend horizontally along a first direction from the memory-array region into a connection region, the same minimum horizontal thickness being in a second direction that is orthogonal to the first direction.

9. The method of claim 6 wherein the conductive-via constructions are a first set, and further comprising:
forming a second set of conductive-via constructions in the connection region that individually directly electrically couple to individual of the access lines that are different from the individual access lines that the first set is directly electrically coupled to.

10. The method of claim 9 wherein the first and second sets of conductive-via constructions have different minimum horizontal thicknesses relative one another.

11. The method of claim 10 wherein the conductive-via constructions of the second set individually have larger minimum horizontal thickness than the conductive-via constructions of the first set.

12. Memory circuitry comprising:
a memory-array region comprising vertically-alternating insulative tiers and memory-cell tiers, memory cells in the memory-cell tiers that individually comprise a horizontal transistor comprising a gate, the gate comprising part of one of a plurality of horizontal conductive access lines that individually directly electrically couple together multiple of the gates of different ones of the horizontal transistors that are in the same memory-cell tier, the access lines in different ones of the memory-cell tiers being in a vertical stack wherein the access lines in the different ones of the memory-cell tiers laterally overlap one another, the access lines and the vertical stack extending horizontally along a first direction from the memory-array region into a connection region; and
the connection region comprising conductive-via constructions that individually directly electrically couple to individual of the access lines, individual of the conductive-via constructions comprising a vertically-elongated conductive portion that is laterally-spaced from the vertical stack in a second direction that is orthogonal to the first direction, two of the conductive-via constructions being in a single straight-line vertical cross-section in the second direction on opposite second-direction sides of the vertical stack.

13. The memory circuitry of claim 12 wherein the two are a first two and comprising a second two of the conductive-via constructions in another single straight-line vertical cross-section in the second direction on the opposite second-direction sides of the vertical stack, the first two being laterally-spaced from the second two in the first direction.

14. The memory circuitry of claim 12 wherein the horizontal transistor comprises channel material that is operatively proximate the gate, the channel material extending horizontally from the memory-array region into the connection region.

15. The memory circuitry of claim 14 wherein the channel material in individual of the memory-cell tiers is vertically thickest in the connection region laterally of one of the second-direction sides of the vertical stack.

16. The memory circuitry of claim 15 wherein the channel material in individual of the memory-cell tiers is vertically thickest in the connection region laterally of only one of the second-direction sides of the vertical stack.

17. The memory circuitry of claim 16 wherein none of the channel material in individual of the memory-cell tiers in the connection region is laterally of the other one of the second-direction sides of the vertical stack.

18. Memory circuitry comprising:
a memory-array region comprising vertically-alternating insulative tiers and memory-cell tiers, memory cells in the memory-cell tiers that individually comprise a horizontal transistor comprising a gate, the gate comprising part of one of a plurality of horizontal conductive access lines that individually directly electrically couple together multiple of the gates of different ones of the horizontal transistors that are in the same memory-cell tier, individual of the access lines comprising a top access line and a bottom access line, the gate comprising a top gate that is part of the top access line and comprising a bottom gate that is part of the bottom access line, the top and bottom access lines in different ones of the memory-cell tiers being in a vertical stack wherein the top and bottom access lines in the different ones of the memory-cell tiers laterally overlap one another, the top and bottom access lines and the vertical stack extending horizontally along a first direction from the memory-array region into a connection region; and
the connection region comprising conductive-via constructions that individually comprise a conductive part that is vertically between and directly electrically coupled to individual of the top and bottom access lines that are in the same memory-cell tier, individual of the conductive-via constructions comprising a vertically-elongated conductive portion that is laterally-spaced from the vertical stack in a second direction that is orthogonal to the first direction, two of the conductive-via constructions being in a single straight-line vertical cross-section in the second direction on opposite second-direction sides of the vertical stack.

19. The memory circuitry of claim 18 wherein the two are a first two and comprising a second two of the conductive-via constructions in another single straight-line vertical cross-section in the second direction on the opposite second-direction sides of the vertical stack, the first two being laterally-spaced from the second two in the first direction.

20. The memory circuitry of claim 18 wherein the horizontal transistor comprises channel material that is operatively between the top and bottom gates, the channel material extending horizontally from the memory-array region into the connection region.

21. The memory circuitry of claim 20 wherein the channel material in individual of the memory-cell tiers is vertically thickest in the connection region laterally of one of the second-direction sides of the vertical stack.

22. The memory circuitry of claim 21 wherein the channel material in individual of the memory-cell tiers is vertically thickest in the connection region laterally of only one of the second-direction sides of the vertical stack.

23. The memory circuitry of claim 22 wherein none of the channel material in individual of the memory-cell tiers in the connection region is laterally of the other one of the second-direction sides of the vertical stack.
